(19) United States
(12) Patent Application Publication
(10) Pub. No.: US 2026/0342357 A1
(43) Pub. Date: Oct. 29, 2026

(54) Prime-Resonance Audio/Vision Codec and Related Methods, Systems, Hardware, and Computer-Readable Media for Lossless and Near-Lossless Signal Compression Using Prime- Indexed Gaussian-Spike Bases

(71) Applicant: Jonathan Washburn, Austin, TX (US)

(72) Inventor: Jonathan Washburn, Austin, TX (US)

(21) Appl. No.: 19/651,738

(22) Filed: Apr. 19, 2026

Related U.S. Application Data
(60) Provisional application No. 63/794,530, filed on Apr. 25, 2025.

(51) Int. Cl. H03M 7/30

(52) U.S. Cl. CPC H03M 7/3066; H03M 7/3064; H03M 7/6005; H03M 7/6011

(57) ABSTRACT

Systems, methods, and non-transitory computer-readable media compress and decompress signals using sparse representations formed from prime-indexed Gaussian-spike atoms and a coded residual. An encoder partitions an input signal into processing units, derives atom-definition parameters from fixed profile constants and from sampling and unit configurations, and performs sparse decomposition to produce a spike list of prime identifiers, center identifiers, and coefficients. The encoder defines an integer-domain residual as an exact difference between the processing unit and a deterministic integer-domain mapping of a sparse estimate, and entropy codes the spike list and residual into a bitstream. A decoder parses the bitstream, regenerates atoms under the declared profile, accumulates the sparse estimate, applies the mapping rule, and combines the estimate with the decoded residual for bit-perfect lossless reconstruction. Embodiments support audio, images, video, medical imaging, and telemetry.

### CROSS-REFERENCE TO RELATED APPLICATIONS

This application claims the benefit of U.S. Provisional Patent Application No. 63/794,530, filed Apr. 25, 2025, the entire disclosure of which is incorporated herein by reference.

### BACKGROUND OF THE INVENTION

The subject matter of this disclosure generally relates to digital signal compression and decompression and, more particularly, to lossless and near-lossless compression of audio, video, and other digitally represented signals using structured basis functions and sparse representations that are deterministically reproducible at both an encoder and a decoder.

Digital media systems commonly store and transmit audio samples and video pixels in representations such as pulse-code modulation (PCM) for audio and raster frames for video, where each sample or pixel is represented by a fixed number of bits and the resulting bitrate scales directly with sample rate, bit depth, and channel count. Lossless codecs reduce bitrate while requiring exact reconstruction of the original samples or pixels, which is a demanding constraint because any mismatch between encoder and decoder behavior, any non-determinism in parameter selection, or any approximations in arithmetic may produce bit errors and thus fail operational requirements for archival storage, studio workflows, medical imaging, compliance logging, and other applications where exact recall is required.

Many established lossless audio codecs rely on linear predictive coding or related prediction strategies followed by entropy coding of a residual, and such discussion is for context only and is not an admission of prior art. A typical architecture attempts to model each sample as a function of previous samples and then codes the prediction error as a sequence of integers with reduced entropy relative to the original waveform. While effective for broad classes of audio, these approaches can be limited by the extent to which a low-order linear predictor captures the relevant structure, particularly for signals with time-varying spectra, dense transients, mixed tonal and noise-like components, and multi-channel correlations that vary over time. When the predictor does not capture the salient structure, the residual remains relatively high-entropy, and the codec expends bits to represent residual randomness that is not meaningfully reduced by the chosen model. A further operational limitation is that prior systems often treat “lossless” as synonymous with “prediction plus entropy coding,” and therefore the compression efficiency is closely coupled to how well a predictor family matches the source statistics rather than to whether the signal admits a sparse representation in a basis tailored to its structure.

Many established lossless video codecs similarly use spatial and temporal predictors and then entropy-code prediction errors, sometimes combined with block-based transforms or context modeling, and such discussion is for context only and is not an admission of prior art. Video codecs must address luma/chroma planes, high-resolution imagery, motion, texture, and edges, and the codec's effectiveness depends on how well its prediction and context modeling capture correlations within and between frames. When prediction misses important structure, the codec again produces a residual with significant redundancy that is difficult to compress without increasing model complexity, state, and computational cost. Additionally, prior video architectures often rely on generic transforms such as discrete cosine transforms, fast Fourier transforms, or wavelet transforms that can spread energy across many basis coefficients, particularly for content with sharp features, non-stationary behavior, or structure that does not align with the transform's implicit assumptions. This energy spreading can lead to less sparse coefficient distributions and therefore increases the coding burden, even in nominally lossless settings where coefficients must be represented exactly rather than being quantized away. A recurring technical shortcoming in many prior approaches is that their transforms and basis functions are generic and broadly applicable rather than being structured to yield sparse representations for natural signals across multiple modalities. Generic bases may be orthogonal or convenient to compute, yet still produce dense coefficient sets for real-world inputs, which forces the codec to spend bits representing many small coefficients or to rely on post-processing steps that do not materially reduce entropy under exact reconstruction constraints. In practice, this can manifest as limited compression ratio improvements when moving from one conventional lossless codec to another, because several codecs are effectively spending bits on different forms of the same residual redundancy. This limitation matters operationally because storage, transmission cost, and real-time compute scale strongly with bitrate, and even modest bitrate reductions can significantly improve streaming viability, device power consumption, and cloud cost, while large improvements can enable entirely new workflows such as lossless high-resolution mastering over constrained networks, long-term archival of large collections, and low-latency professional collaboration.

Another shortcoming of prior art is that many systems achieve their best performance only after selecting and tuning parameters that are content-dependent or platform-dependent, including predictor orders, block sizes, heuristic thresholds, psychoacoustic settings (in lossy systems), context-model selection, or codec-specific modes that require careful optimization, and such discussion is for context only and is not an admission of prior art. Such tuning increases engineering complexity and can impair reproducibility, particularly when implementations must match bit-for-bit across different processors, compilers, GPU kernels, FPGA designs, and ASIC decoders. In strict lossless pipelines, determinism is not merely a preference; it is a requirement for bit-perfect reconstruction. If an encoder uses a parameter derivation path that is not precisely reproducible at the decoder, or if the encoder uses floating-point approximations that the decoder cannot match, then the purportedly lossless system becomes fragile in practical deployments. Hardware implementability is also a limiting factor in prior systems. High-performance codec pipelines increasingly rely on parallel compute resources such as GPUs, vector units, and specialized accelerators, and they also target low-power decoding on embedded devices and ASICs. Prior art methods that are heavily branch-dependent, that require complex adaptive models with large state, or that involve transforms not readily mapped to fixed-function arithmetic may impose barriers for deterministic hardware implementations, and such discussion is for context only and is not an admission of prior art. Additionally, a codec architecture that is efficient in software may not translate cleanly into FPGA or ASIC logic without introducing approximations, precision loss, or unpredictable timing behavior, each of which can jeopardize strict lossless reconstruction or complicate verification. In high-stakes environments such as medical imaging, regulatory logging, and forensics, the inability to provide deterministic decoding behavior, auditability, and verification of bit-perfect recall is an operational deficiency rather than a mere performance issue.

Accordingly, there is a need for improved systems and methods for lossless and near-lossless compression that provide a concrete, reproducible technical mechanism for representing signals sparsely in a structured basis, that enable deterministic encoder/decoder agreement on basis parameters and atom generation, that reduce residual entropy by capturing signal structure in a sparse representation rather than relying solely on generic prediction, and that are implementable across software and hardware platforms including general-purpose processors, GPUs, FPGAs, and ASICs. There is also a need for a unified architecture that can be applied to multiple data types, including audio, video, still images, medical imaging data, and telemetry streams, while maintaining clear mode distinctions for lossless, near-lossless, and lossy operation so that system designers can select strict bit-perfect reconstruction where required and controlled approximation where permissible, without altering the fundamental codec pipeline or requiring a separate family of codec designs.

### SUMMARY OF THE INVENTION

This disclosure provides systems, methods, and non-transitory computer-readable media for compressing and decompressing digitally represented signals using a prime-indexed Gaussian-spike basis and a sparse decomposition process that produces a compact spike representation together with a separately coded residual, wherein, in certain embodiments consistent with Recognition Science (RS) (also referred to as the Recognition Physics framework), the prime indexing and fixed normalized parameters can correspond to Recognition-Science prime spectra and can be treated as profile-defined constants to support deterministic reproduction. The disclosed architecture is designed so that an encoder and a decoder can deterministically agree on the basis parameters, atom generation, and data structures needed to reconstruct an input signal in a lossless mode with bit-perfect reconstruction, and can also support near-lossless and lossy modes using objectively defined stopping criteria, thresholds, and control rules. All embodiments share a single core codec pipeline including deterministic parameter derivation, prime-indexed Gaussian-spike dictionary definition, sparse decomposition producing a spike list, residual coding under a declared mode policy, and deterministic regeneration and reconstruction, with modality-specific embodiments applying the same pipeline to different input representations. The embodiments described herein share a single core inventive concept of deterministic reconstruction in an integer representation domain in which a sparse estimate is mapped under a declared deterministic mapping rule and combined with an exact integer-domain residual, and audio, image/video, medical imaging, and telemetry embodiments are exemplary applications of that same codec pipeline rather than distinct inventions.

In one aspect, a compression method includes receiving an input signal represented as digital samples, pixels, or other discrete values; partitioning the input signal into blocks, frames, tiles, or other processing units; and representing each unit as a sparse combination of basis atoms selected from a dictionary of prime-indexed Gaussian-spike atoms. A sparse decomposition engine iteratively selects atoms that best match a current residual, records atom descriptors and coefficients into a spike list, updates the residual by subtracting the selected atoms, and terminates according to a selected operating mode. In a lossless mode, the sparse decomposition may be constrained by a spike budget and the remaining residual is encoded exactly so that the decoder can reconstruct the original unit with bit-perfect fidelity. In a near-lossless mode, the sparse decomposition may terminate when a residual-energy criterion is satisfied, and the residual may be coded with reduced precision or otherwise represented according to the near-lossless requirements. In a lossy mode, the decomposition may be truncated and the residual may be omitted or simplified, with the truncation rule providing an objective control knob for rate/distortion behavior.

In another aspect, the disclosed codec uses a deterministic parameter derivation and normalization subsystem that maps fixed, dimensionless normalized basis parameters into signal-grid parameters based on a sampling rate and a processing-unit size. The basis atoms are defined as Gaussian-windowed oscillatory functions indexed by prime numbers, with atom center frequencies determined as prime multiples of a base frequency and with atom widths determined by a width parameter, where a “Gaussian-spike atom” includes an envelope term having a Gaussian form and an oscillatory term having a cosine or sine form, evaluated on a declared discrete sample grid. In preferred embodiments, the normalized base frequency and normalized width are derived from fixed constants and are mapped to a given signal's sampling grid using deterministic formulas so that both the encoder and decoder can reproduce identical atom definitions without exchanging floating-point tuning parameters or content-dependent heuristics. In this way, the basis can be treated as not requiring per-stream tuned parameters at the codec level in certain embodiments, and only the mapping from normalized parameters to a given sampling grid depends on externally supplied signal configuration values such as sampling rate and block length.

In another aspect, a dictionary construction subsystem organizes candidate atoms by prime index, time center, and optional phase and/or scale variants. The dictionary may be stored explicitly in memory, represented as a parameter table and/or waveform table, generated procedurally on demand, or implemented as a hybrid where a compact parameter memory enables deterministic regeneration of atom waveforms. The prime-indexed center frequencies are irregularly spaced relative to uniformly spaced harmonic series or fixed-bin transforms, and the disclosed architecture exploits this irregularity to reduce mutual coherence among candidate atoms under the declared candidate ordering, thereby improving convergence of sparse selection methods such as matching pursuit and reducing spike-list size and residual entropy for a given lossless reconstruction constraint. The dictionary may be bounded by bandwidth constraints, Nyquist criteria, tile geometry, and other implementation limits, and may be configured to target practical sizes suitable for software, GPU, FPGA, and ASIC implementations.

In another aspect, the sparse decomposition engine performs matching pursuit or a functionally equivalent sparse selection procedure. For each processing unit, the engine initializes a residual to the input unit and iterates through a selection loop. In each iteration, the engine evaluates inner products between the current residual and candidate atoms to identify a best-matching atom, stores a prime index and time center for the selected atom, computes and stores a coefficient, updates the residual, and checks termination conditions. Objective termination conditions can include, for example, a maximum number of selected atoms, a residual-energy threshold relative to an original unit energy, and mode-dependent controls that determine whether the residual will be coded exactly, coded approximately, or discarded. The spike list thus functions as a machine-actionable sparse representation that reduces the entropy of what remains to be coded and that can be reproduced at the decoder using deterministic regeneration of the atoms.

In another aspect, an entropy coding subsystem converts the spike list and residual information into a compressed bitstream. In certain embodiments, prime indices are encoded using a code family effective for a distribution in which smaller primes occur more frequently, such as Golomb-Rice coding. Time-center values are encoded using fixed-length codes or entropy codes according to the selected stride and time-center grid. Coefficients are represented with a selected precision and are entropy-coded using arithmetic coding, range coding, or another entropy coder using a coefficient distribution model, such as a Laplacian or approximately Laplacian model. In lossless mode, the residual is coded exactly, for example by applying a predictor to the residual and entropy-coding integer prediction errors, thereby ensuring that the combination of decoded spikes and decoded residual yields bit-perfect reconstruction at the decoder. In certain embodiments, the bitstream includes headers that signal mode selection, dictionary configuration, predictor configuration, coding tables, and other information used by the decoder to reproduce the encoder's interpretation of the bitstream.

In another aspect, a decoder reconstructs a signal processing unit by parsing the bitstream, decoding the spike list and residual, deterministically regenerating the same prime-indexed Gaussian-spike atoms from the signaled configuration and the shared parameter derivation rules, summing the regenerated atoms scaled by the decoded coefficients to form a reconstructed sparse component, and combining the reconstructed sparse component with the decoded residual. For overlap-based framing embodiments, an overlap-add engine combines reconstructed blocks to form a continuous output signal. For tile-based embodiments, reconstructed tiles are assembled into reconstructed planes and reconstructed frames, and color space conversion or plane recombination may be performed to provide an output signal. In lossless mode, the decoder's output matches the original input signal exactly.

In another aspect, the disclosed codec applies to audio signals represented as PCM samples and can operate over a range of sample rates, bit depths, and channel configurations including mono, stereo, and multi-channel formats. In certain embodiments, blocks and frame hops are selected so that overlap processing provides smooth reconstruction and efficient decomposition. Multi-channel embodiments can exploit inter-channel correlation by encoding difference channels, mid/side representations, or other correlated channel transforms prior to sparse decomposition and residual coding.

In another aspect, the disclosed codec applies to video and image signals represented as raster pixel values, including RGB and YUV formats. In certain embodiments, each plane is processed in tiles, and the basis is extended to a two-dimensional separable form in which a two-dimensional atom is formed as a product of a first one-dimensional prime-indexed atom along a first dimension and a second one-dimensional prime-indexed atom along a second dimension. The separable structure enables efficient computation using row-column decomposition and supports luma/chroma handling, subsampling, and high-dynamic-range embodiments such as 10-bit and 12-bit HDR representations. The disclosed architecture also applies to medical imaging data, including DICOM data, CT data, MRI data, and volumetric image sequences represented as slices.

In another aspect, the invention includes hardware and software implementations. An encoder and/or decoder may be implemented as software executed by one or more processors, as firmware implemented by a state machine, as a GPU-accelerated implementation using parallel dot-products and reductions, as an FPGA implementation using ROMs, DSP slices, and pipelined arithmetic and coding cores, or as an ASIC implementation including a decode-only embodiment for low-power devices. Non-transitory computer-readable media store instructions that, when executed by one or more processors, cause performance of any disclosed method, including encoding, decoding, sparse decomposition, entropy coding, deterministic parameter derivation, and deployment workflows.

In another aspect, the disclosed codec supports deployment embodiments including archival music storage and streaming, studio mastering workflows for multi-track session files, medical imaging archival in PACS environments, satellite telemetry transmission and storage, low-latency broadcast compression, and cloud transcoding services that accept media uploads, encode content using the disclosed prime-resonance basis, and provide encoded outputs along with verification information such as hashes or audit metadata. These deployment embodiments are exemplary use contexts of the same codec architecture, record format, deterministic parameter mapping, sparse decomposition, and residual policy, and do not require additional codec structure unless expressly recited. In these embodiments, the technical effect achieved by the disclosed architecture is a reduction in bitrate for signals that admit sparse representations in the prime-indexed Gaussian-spike basis while maintaining deterministic decode behavior, reproducible reconstruction rules, and mode-controlled tradeoffs between bit-perfect recall and controlled approximation.

The disclosed codec provides a technical improvement in deterministic lossless and near-lossless compression by using prime-indexed atom addressing with deterministic parameter derivation and by defining an exact integer-domain residual after applying the same declared mapping rule used at decode, thereby enabling bit-perfect reconstruction independent of platform-specific floating-point variability. The foregoing Summary is provided to introduce selected concepts in a simplified form and is not intended to identify key features or essential features of the claimed subject matter, nor is it intended to limit the scope of the claims. Additional aspects, embodiments, and technical effects are described below in the Detailed Description and illustrated in the accompanying drawings.

### BRIEF DESCRIPTION OF THE DRAWINGS

FIG. 1 is a block diagram of an exemplary encoder architecture for a prime-resonance codec, showing an input interface, block former, deterministic normalization engine, basis generator coupled to a dictionary memory, sparse decomposition engine, entropy coding stages for prime indices, time centers, coefficients, and residual data, and a bitstream packer producing a compressed output bitstream.

FIG. 2 is a block diagram of an exemplary parameter derivation and deterministic normalization subsystem, showing a constant store providing basis-defining constants, generation of a normalized base frequency and normalized width, mapping of the normalized parameters to signal-grid parameters using a sampling-rate input and a block-length input, and output of parameters used to deterministically define atoms for use by both encoder and decoder.

FIG. 3 is a block diagram of an exemplary dictionary construction, atom addressing, and atom-selection subsystem, showing a prime set, a time-center set defined by a stride or center grid, optional phase and scale variant sets, an address generator, parameter and/or waveform tables, generation of candidate atom descriptors, and output of selected atom descriptors for use by a sparse decomposition engine.

FIG. 4 is a block and flow diagram of an exemplary sparse decomposition engine using matching pursuit, showing residual initialization, repeated evaluation of inner products with candidate atoms, argmax selection of a best-matching atom, formation of a spike list containing prime indices, time centers, and coefficients, residual update by subtraction of selected atoms, and mode-dependent termination based on one or more objective criteria.

FIG. 5 is a block diagram of an exemplary entropy coding and bitstream formation subsystem, showing coding of prime indices, time centers, coefficients, and residual information, generation of header fields that signal operating mode and configuration information, and formatting of a compressed payload into a bitstream.

FIG. 6 is a block diagram of an exemplary decoder and reconstruction subsystem, showing parsing of a compressed payload, decoding of a spike list and residual data, deterministic regeneration of atoms using shared parameter derivation rules, accumulation of regenerated atoms scaled by decoded coefficients, combination with a decoded residual, and output of reconstructed signal blocks, tiles, planes, frames, and/or continuous output streams.

FIG. 7 is a block and flow diagram of an exemplary audio embodiment, showing frame buffering, windowing, overlap processing, generation and coding of an audio spike list and an audio residual, and reconstruction of an output audio stream for storage or playback, including mono, stereo, and multi-channel embodiments.

FIG. 8 is a block and flow diagram of an exemplary video embodiment, showing color-space conversion, separation of luma and chroma planes, optional plane scaling, tile formation, two-dimensional basis application, tile decomposition and coding, and reconstruction of output frames for storage, display, or transmission.

FIG. 9 is a block diagram showing formation and use of a two-dimensional separable prime-resonance atom, including generation of a horizontal one-dimensional atom and a vertical one-dimensional atom, combination into a two-dimensional atom, and row/column processing to support efficient decomposition and reconstruction of tiled image content.

FIG. 10 is a block diagram of exemplary hardware implementation platforms, showing processor, memory, dictionary ROM, and representative accelerator resources including a GPU, FPGA fabric, and an ASIC, along with dot-product, reduction, and entropy coding cores suitable for implementing the disclosed encoding and decoding pipelines.

FIG. 11 is a block diagram of exemplary alternative operational embodiments, including streaming operation with low-latency buffering, multi-channel processing with inter-channel correlation handling, HDR processing paths, adaptive dictionary embodiments that learn supplementary atoms, and lossy-mode operation in which decomposition is truncated and residual coding is omitted or simplified.

FIG. 12 is a block diagram of exemplary deployment environments, including archival music systems, studio mastering systems, medical imaging PACS environments, cloud transcoding services, live broadcast encoder/receiver systems, and telemetry transmission systems, each of which can employ the disclosed codec to generate compressed outputs and deterministically reconstruct decoded content.

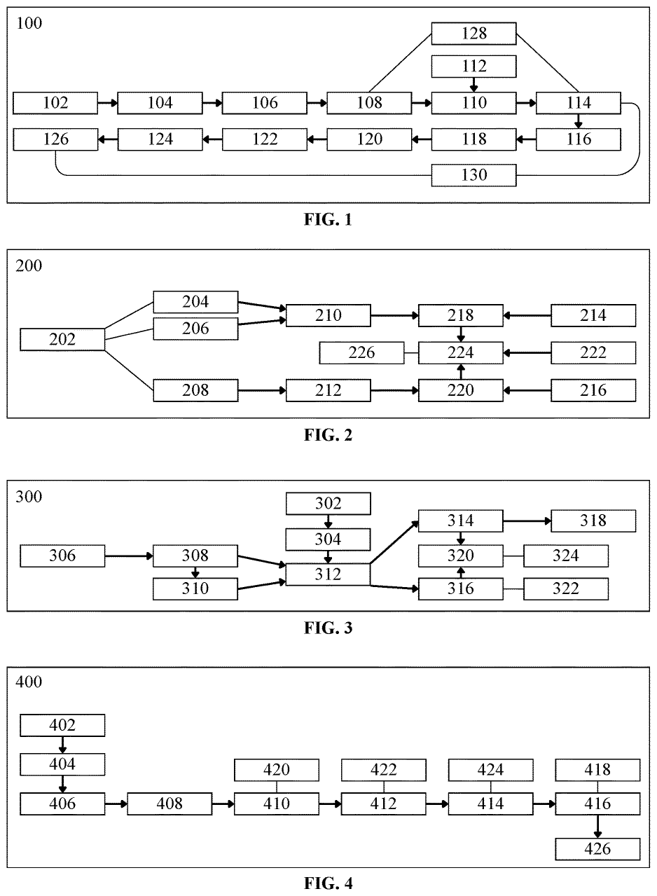

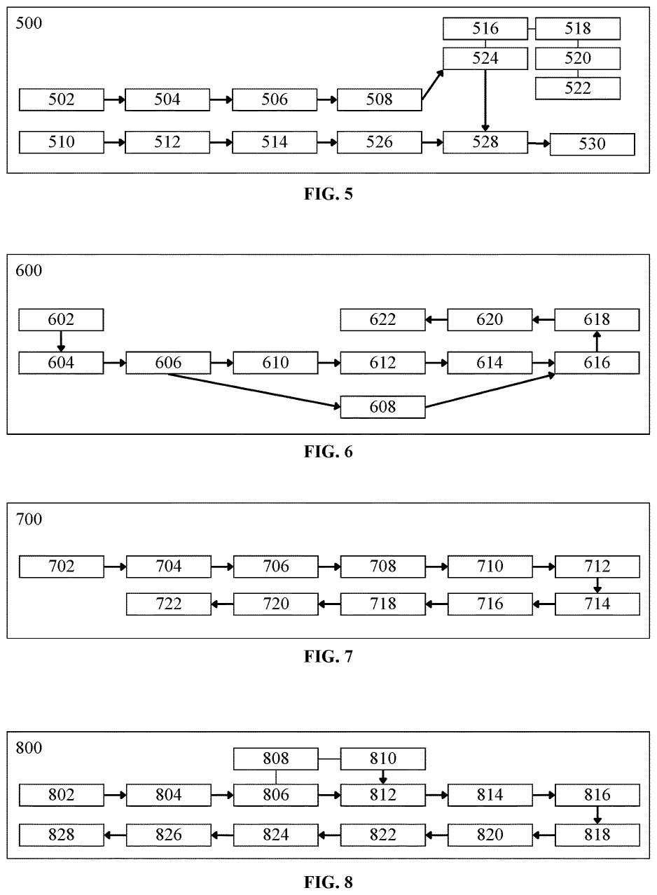

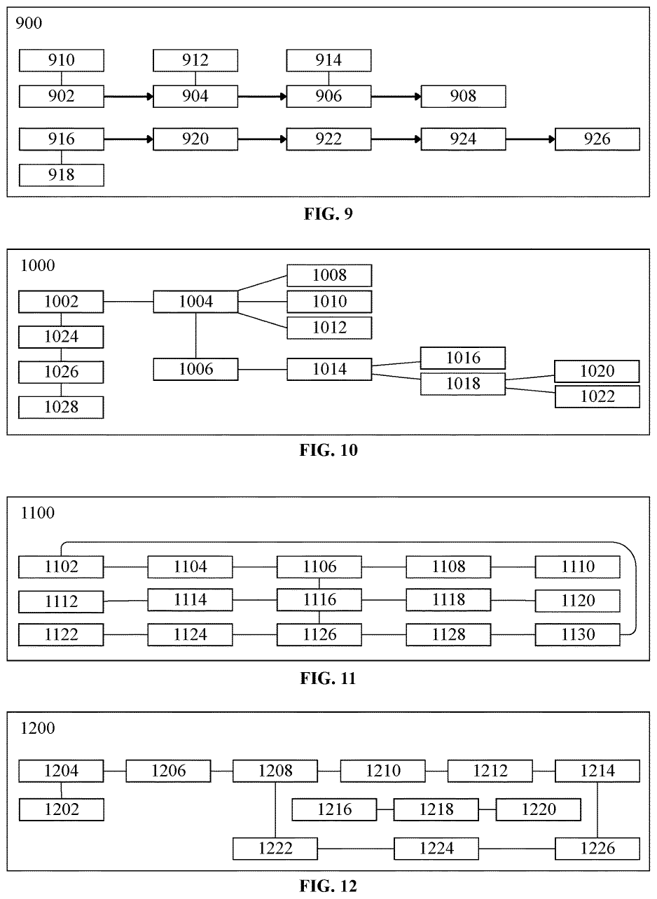

### DETAILED DESCRIPTION OF THE INVENTION

An encoder/decoder codec is provided in which an input signal is partitioned into processing units, each processing unit is represented as a sparse combination of prime-indexed Gaussian-spike atoms plus a separately coded residual, and a decoder reconstructs each processing unit by regenerating the same atoms from the same deterministic configuration and combining a regenerated sparse component with a decoded residual.

An input signal can be a one-dimensional sequence of discrete-time samples, including audio samples and telemetry samples, and an input signal can be a two-dimensional array of values, including image planes, and an input signal can be a sequence of two-dimensional arrays, including video frames, and an input signal can be a volumetric dataset represented as a sequence of slices, including medical imaging data. A processing unit can be an audio block of N samples per channel, including overlapped audio frames advanced by a hop size, and a processing unit can be an image tile or a video tile within a plane, and a processing unit can be a tile within a medical image slice, where the partitioning is deterministic under a declared configuration. An atom is a basis function selected from a dictionary and used as a component of a sparse representation of a processing unit, a prime index identifies a prime number p or an identifier that resolves to p in a decoder under a declared rule, a profile identifier identifies a declared profile that fixes at least arithmetic domain rules, mapping rules, identifier-interpretation rules, candidate enumeration ordering, and tie-breaking rules used by the decoder for deterministic decoding, and, in one embodiment, non-prime indices are excluded from the dictionary in a lossless profile. A mapping rule identifier identifies a predetermined mapping from a sparse estimate into an integer representation domain, including at least rounding behavior, saturation behavior, and any declared normalization or scaling interpretation needed so that encoder-side and decoder-side application of the mapping rule produce the same integer-domain sparse estimate. A center identifier identifies a discrete center position within a processing unit at which an atom is centered, and a coefficient is a scalar weight associated with a selected atom. A spike list is a machine-actionable data structure that includes, for each selected atom, at least a prime identifier, a center identifier, and a coefficient, and a spike list can additionally include discrete variant identifiers such as a phase variant identifier, a sign variant identifier, or a scale variant identifier when such variants are enabled. A residual is a remainder associated with a processing unit after subtracting a sparse component from an original processing unit in a declared representation domain.

A lossless operating mode is provided in which reconstructed output values equal corresponding input values exactly in the same representation domain, including identical integer PCM samples for audio embodiments and identical integer pixel values for image and video embodiments. A near-lossless operating mode is provided in which an objective distortion criterion is satisfied under a declared evaluation rule, including a residual-energy ratio bound or a maximum absolute error bound, and the criterion is reproducible. A lossy operating mode is provided in which an objective truncation policy is applied, including limiting spike selection and omitting or simplifying residual coding, to reduce bitrate under a deterministic rule.

Deterministic reconstruction is achieved by defining how parameters, centers, coefficients, residuals, and bitstream fields are represented and interpreted under a declared profile, including rules for rounding, scaling, saturation, candidate ordering, tie-breaking, and a declared deterministic mapping rule that specifies how a sparse estimate is mapped into an integer representation domain (i) to define an exact integer-domain residual and (ii) to define decoder-side reconstruction, wherein the integer representation domain is a declared integer-valued domain corresponding to the input representation, including a signed PCM integer domain for audio and an integer pixel-value domain for image/video, and wherein the mapping rule includes declared rounding and saturation behavior. As used herein, “deterministic” means that for a declared profile identifier and the same input values, the encoder and decoder (or two decoders) will produce identical interpreted parameter values and identical decoded output values because the profile fixes (i) arithmetic domain, rounding, and saturation, (ii) candidate ordering, and (iii) tie-breaking. As used herein, an “objective distortion criterion” is a numeric bound evaluated by a declared rule, including at least one of (i) a residual-energy ratio threshold or (ii) a maximum absolute error bound, where the threshold value is signaled or fixed by profile. As used herein, an “objective selection metric” is a deterministic numeric scoring rule used to rank candidate atoms, including a correlation magnitude metric |<r,g>| computed under a declared arithmetic domain and a declared tie-breaking rule. In one implementation, computations that influence decoding are performed in a fixed-point domain with declared scaling and rounding rules. In another implementation, computations are performed in a floating-point domain with declared precision and declared evaluation and reduction rules, and exact reconstruction in lossless mode is ensured by coding a residual exactly in an integer representation domain such that any discrepancy introduced by floating-point arithmetic is corrected by the residual.

The encoder system 100 receives input samples or pixels from the input signal source 102 through the input interface 104, where the input interface 104 buffers the input and produces a canonical internal representation used by downstream modules. The block former 106 partitions the input into processing units according to a declared configuration, including block size and hop size for audio embodiments and tile size and tile ordering for image and video embodiments. The deterministic normalization engine 108 derives signal-grid parameters used to define atoms for each processing unit based on configuration inputs and shared mapping rules, including mapping normalized basis parameters to the sampling grid and defining a permissible center grid. The basis generator 110 generates or addresses candidate atoms based on the derived parameters and uses dictionary memory 112 to obtain parameter entries, waveform templates, and/or waveform samples that enable deterministic atom regeneration. The sparse decomposition engine 114 selects atoms and coefficients to form a spike list for each processing unit and produces a residual signal for the processing unit. The coefficient formatter 116 converts coefficients into a declared coding domain, including representing coefficient sign and magnitude and applying a declared scaling rule where used. The prime-index coder 118 encodes prime identifiers for the spike list, the center coder 120 encodes center identifiers for the spike list, and the coefficient coder 122 encodes coefficient values for the spike list. The residual coder 124 encodes residual information associated with each processing unit, including exact residual coding for lossless mode. The bitstream packer 126 packs header fields and payload fields into a compressed bitstream according to a declared field order. The control processor 128 coordinates control flow, configuration selection, and scheduling of compute resources, and the working memory 130 stores intermediate buffers including residual buffers, spike list buffers, and coder state.

In one embodiment, the compressed bitstream output by the bitstream packer 126 includes a stream header followed by a sequence of processing-unit records, where the stream header identifies a codec version identifier, a profile identifier, a signal type identifier, and configuration parameters needed to interpret the stream. In one embodiment, each processing-unit record includes a mode indicator identifying lossless, near-lossless, or lossy operation, a spike-count indicator identifying how many spike entries are present, an encoded spike list payload containing prime identifiers, center identifiers, and coefficients, and an encoded residual payload containing residual information. In one embodiment, a dictionary configuration identifier is included in a header to indicate the prime list rule, the center-grid rule, and any enabled discrete variants, and a residual coder configuration identifier is included to indicate how residuals are encoded and decoded.

In one lossless embodiment, the sparse decomposition engine 114 selects a finite number of spikes according to a declared selection rule and a declared budget and provides a residual to the residual coder 124, and the residual coder 124 encodes the residual exactly in the integer representation domain of the input signal. In one embodiment, the residual coder 124 encodes the residual directly as integers. In another embodiment, the residual coder 124 applies a predictor and encodes integer prediction errors, where predictor configuration is declared and reproducible. In lossless mode, the encoded residual payload is sufficient for exact reconstruction when combined with a regenerated sparse component under a declared reconstruction rule. In one embodiment providing exact reconstruction using an exact residual, the encoder forms a sparse estimate s for a processing unit in an internal numeric domain, maps s into an integer reconstruction domain using a declared mapping rule, and defines a residual r as the exact integer difference between an original integer processing unit x and the mapped sparse estimate, and the residual coder 124 encodes r exactly. In that embodiment, the decoder reconstructs x by regenerating the same sparse estimate, applying the same mapping rule to obtain the integer-domain sparse estimate, and adding the exactly decoded residual r, thereby producing output values equal to the original input values exactly in the integer domain.

In one near-lossless embodiment, the sparse decomposition engine 114 terminates atom selection according to an objective distortion criterion, and the residual coder 124 encodes residual information according to a declared rule such that the decoder reconstruction satisfies the criterion. In one embodiment, the objective distortion criterion is a residual-energy ratio bound computed under a declared energy computation rule, and the criterion parameter value is signaled or implied by profile. In another embodiment, the objective distortion criterion is a maximum absolute error bound computed under a declared measurement rule, and the criterion parameter value is signaled or implied by profile. In near-lossless embodiments, residual coding can be performed at reduced precision under a declared rule or can be omitted when the criterion is satisfied by the sparse component.

In one lossy embodiment, the sparse decomposition engine 114 selects at most a declared number of spikes and the residual coder 124 omits residual coding or encodes a reduced residual representation under a declared rule, and the mode indicator signals the lossy policy. In one embodiment, the lossy policy is defined by a maximum spike count and a coefficient magnitude threshold, and coefficients below the threshold are not recorded. In another embodiment, the lossy policy includes coding only a limited-precision residual representation. The lossy policy is deterministic under the declared configuration.

A deterministic candidate ordering and tie-breaking rule is applied to avoid ambiguity in atom selection when two candidates compare equal under a declared compare rule. In one embodiment, candidate atoms are ordered by increasing prime identifier, then increasing center identifier, and then increasing variant identifier when variants are enabled, and when two candidates compare equal under the declared compare rule, the earlier candidate in the ordering is selected. In one embodiment, the compare rule is exact equality in a fixed-point domain. In another embodiment, for near-lossless or lossy operation, the compare rule includes a declared tolerance and treats values within the tolerance as equal for tie-breaking.

The encoder system 100 can be implemented entirely in software executed by the control processor 128 using the working memory 130, where dictionary memory 112 is stored in system memory, mass storage, or a memory-mapped file, and where compute-intensive correlation operations within the sparse decomposition engine 114 can be accelerated using vector instructions. The encoder system 100 can also be implemented using heterogeneous computing, where correlation and selection operations are offloaded to an accelerator and entropy coding operations are performed on a processor, provided that arithmetic rules and reduction ordering are consistent with the declared profile and that lossless mode reconstruction is ensured by exact residual coding in the integer domain as described above.

The encoder system 100 can output integrity information in the compressed bitstream to support error detection and recovery in transport scenarios, including per-record checksums and periodic resynchronization markers, where the decoding behavior on detection of corruption is deterministic and applies a declared handling policy including at least one of discarding a corrupted record, outputting gaps or flags, and producing a defined concealment output, and does not silently substitute unverified output values for corrupted payloads.

A deterministic parameter derivation subsystem 200 provides a shared, reproducible mapping from configuration inputs to atom-definition parameters so that an encoder and a decoder can generate consistent prime-indexed Gaussian-spike atoms without relying on content-dependent tuning. The parameter derivation subsystem 200 stores immutable constants and uses deterministic arithmetic rules to derive normalized parameters and then maps those normalized parameters onto a signal grid defined by a sampling configuration and a processing-unit configuration.

A constant store 202 provides constant values used by the parameter derivation subsystem 200, including a phi parameter store 204 that provides phi, an X_opt parameter store 206 that provides X_opt, and an R_RP parameter store 208 that provides R_RP, wherein, in certain embodiments consistent with Recognition Science, phi, X_opt, and R_RP are treated as Recognition-Science-derived constants defining a renormalisation profile for the prime-resonance basis, and wherein the constant store 202 is immutable for a given declared profile so that encoder and decoder use the same constants. In one embodiment, the phi parameter store 204 stores phi=(1+sqrt(5))/2 and the value is treated as a fixed constant of the profile, wherein phi is stored and interpreted either as an exact symbolic constant or as a fixed-point constant with declared scaling and declared rounding. In one embodiment, the X_opt parameter store 206 stores X_opt=phi/pi as a fixed constant of the profile. In one embodiment, the R_RP parameter store 208 stores R_RP=7/12 as a fixed constant of the profile. In one embodiment, these constants are not transmitted per block; they are treated as a fixed profile definition, and a decoder uses the same profile definition to obtain the same constants.

A delta_loop generator 210 produces a normalized base-frequency parameter that is used to derive a signal-grid base frequency for atom center frequencies. In one embodiment, the delta_loop generator 210 computes delta_loop=X_opt\hat{ }(1+R_RP) using deterministic arithmetic rules defined by the profile. In one embodiment, the exponentiation in delta_loop=X_opt\hat{ }(1+R_RP) is carried out in a fixed-point domain using a declared approximation method with declared rounding so that an encoder and a decoder compute the same delta_loop. In another embodiment, delta_loop is stored as a fixed constant in the constant store 202 so that an encoder and a decoder do not compute exponentiation at runtime and instead fetch the value, provided that the fetched value is the same in both.

A sigma_frac generator 212 produces a normalized width parameter that is used to derive a signal-grid width for atom envelopes. In one embodiment, the sigma_frac generator 212 computes sigma_frac=X_opt*R_RP using deterministic arithmetic rules defined by the profile. In one embodiment, sigma_frac is treated as sigma_norm, and in another embodiment sigma_frac is mapped through an additional deterministic normalization rule, provided that the rule is shared by encoder and decoder.

A sampling-rate input 214 provides sampling configuration information used to map normalized parameters to a signal grid. In one audio embodiment, the sampling-rate input 214 provides an audio sampling rate F_s expressed in Hz. In one telemetry embodiment, the sampling-rate input 214 provides an effective sample rate for a sampled telemetry channel. In one image or video embodiment, the sampling-rate input 214 provides an axis scale used for mapping normalized frequency-like parameters into per-axis basis parameters, and the mapping rule specifies how the axis scale is derived from pixel spacing or tile dimensions where applicable.

A unit-size input 216 provides processing-unit configuration information used to map normalized parameters to a signal grid. In one audio embodiment, the unit-size input 216 provides a block length N in samples. In one embodiment, the unit-size input 216 further implies a hop size and a stride value that define overlap and center-grid behavior under the profile. In one image or video embodiment, the unit-size input 216 provides a tile width and tile height, and the profile defines whether the mapping uses tile width, tile height, or both to determine per-axis parameters for separable processing.

A base-frequency mapper 218 maps a normalized base-frequency parameter into a signal-grid base frequency f0 used to construct prime-indexed center frequencies. In one embodiment, the base-frequency mapper 218 sets f0_norm=delta_loop and maps f0=f0_norm*(F_s/N) when the sampling-rate input 214 provides F_s and the unit-size input 216 provides N. In that embodiment, f0 is a base frequency in Hz, and a prime-indexed center frequency is determined as f_p=p*f0 for prime number p. In another embodiment, the base-frequency mapper 218 maps f0 into a per-sample angular frequency omega0=2*pi f0/F_s and provides omega0 for discrete-time atom evaluation, which can reduce repeated divisions during atom generation. A width mapper 220 maps a normalized width parameter into a signal-grid width sigma used to construct atom envelopes. In one embodiment, the width mapper 220 sets sigma_norm=sigma_frac and maps sigma=sigma_norm*(N/4) for a one-dimensional block of length N. In that embodiment, sigma is a width in samples and is used in an envelope term exp(−((n−n0)\hat{ }2)/(2sigma\hat{ }2)) for integer index n and center index n0. In another embodiment, the width mapper 220 maps sigma into a fixed-point width parameter used to index a precomputed Gaussian envelope table, and the table index rule is deterministic and shared by encoder and decoder.

A center-grid mapper 222 defines permissible center identifiers within a processing unit and defines how each center identifier maps to a center position. In one audio embodiment, the center-grid mapper 222 defines centers on a fixed stride, where the stride is a deterministic function of N, and center identifiers map to integer sample indices n0. In one embodiment, the stride is stride=N/64 and the center-grid mapper 222 maps a center identifier c to n0=c*stride, with boundary handling defined so that n0 remains within the block index range. In one embodiment, the center-grid mapper 222 permits additional centers near block boundaries under a declared rule to reduce boundary artifacts, and any additional centers are declared and enumerated deterministically so that the decoder uses the same center set. In one image or video embodiment, the center-grid mapper 222 defines spatial centers within a tile along each axis, and center identifiers map to integer pixel coordinates within the tile; in a separable two-dimensional embodiment, the center-grid mapper 222 can define independent center identifiers per axis, with mapping rules declared by the profile.

A parameter output 224 provides atom-definition parameters and mapping identifiers for downstream use by the basis generator 110 and dictionary memory 112 and also provides parameters that must be available to a decoder to regenerate atoms. In one embodiment, the parameter output 224 provides values corresponding to f0, sigma, a prime bound p_max derived from f0 and the sampling rate, and a definition of the center grid. In one embodiment, the parameter output 224 provides an identifier of the mapping rule used by the base-frequency mapper 218 and the width mapper 220, allowing a decoder to select the same mapping rule when multiple rules are supported. In one embodiment, the parameter output 224 provides a representation identifier indicating whether the encoder and decoder interpret parameters in fixed-point or floating-point form, and if fixed-point, provides scaling factors used to interpret fixed-point parameter values.

A determinism checker 226 verifies that the parameter derivation and mapping steps applied for a given stream conform to the declared profile and configuration. In one embodiment, the determinism checker 226 validates that the sampling-rate input 214 and the unit-size input 216 are supported values under the profile, validates that the derived f0 and sigma fall within declared bounds, and validates that the center-grid mapper 222 produces a center set consistent with the declared stride rule. In one embodiment, the determinism checker 226 validates that the arithmetic domain identifier for parameter computations is supported and that any rounding and saturation rules required by the profile are applied. In one embodiment, when validation fails, the determinism checker 226 causes the encoder to select a fallback profile with supported configuration values or to signal an error rather than producing a stream that cannot be decoded deterministically.

The parameter derivation subsystem 200 can be implemented so that the decoder independently regenerates the same parameter values from the same configuration, or the bitstream can explicitly carry parameter values or parameter identifiers, provided that the carried values are interpreted under deterministic rules. In one embodiment, the bitstream carries the sampling rate and unit size and carries a profile identifier, and the decoder uses the constant store 202 and the specified mapping rules to compute f0 and sigma identically. In another embodiment, the bitstream carries f0 and sigma as fixed-point values with declared scaling and carries the center-grid rule identifier, and the decoder uses those carried values directly for atom regeneration, while still validating that the values are permitted under the profile.

The parameter derivation subsystem 200 supports deterministic handling of multiple signal classes by treating the mapping as a function that takes declared configuration inputs and produces declared outputs. In one embodiment for audio, the sampling-rate input 214 and unit-size input 216 fully determine f0 and sigma under the mapping rules and determine a time-center grid under the center-grid mapper 222. In one exemplary lossless audio profile, the sampling configuration is F_s=48,000 Hz, the unit size is N=2048 samples, the hop size is N/4, the center-grid stride is N/64, a maximum spike budget k_max of 10 is enforced for each processing unit, and the mapping rule uses round-to-nearest with ties-to-even followed by saturation to a signed 24-bit integer range. In one embodiment for image and video tiles, the unit-size input 216 includes per-axis sizes and the mapping rules produce per-axis parameters for atom generation and per-axis center grids, and the mapping rules specify whether the same normalized parameters are used on both axes or whether axis-specific normalized parameters are derived deterministically. In one exemplary lossless image/video tile profile, the processing unit is an 8×8 tile per plane in an 8-bit or 10-bit integer pixel domain, horizontal and vertical center identifiers use a 4-pixel stride with deterministic boundary handling, and the mapping rule uses the same round-to-nearest with ties-to-even rule and declared saturation behavior on a per-pixel basis.

The deterministic parameter derivation described herein enables consistent atom regeneration at a decoder because atom definitions are derived from (i) fixed constants in the constant store 202 and (ii) declared configuration inputs provided to the sampling-rate input 214 and the unit-size input 216 under shared mapping rules, thereby avoiding content-dependent tuning that could cause encoder and decoder divergence.

A dictionary subsystem 300 provides a deterministic organization of candidate atoms so that an encoder can select atoms in a reproducible manner and a decoder can regenerate the same atoms from the same identifiers and configuration. The dictionary subsystem 300 operates from declared configuration inputs and shared mapping rules and provides a candidate set that is bounded and addressable so that prime identifiers, center identifiers, and any enabled discrete variant identifiers unambiguously identify an atom.

A prime set 302 stores or generates prime numbers that are eligible for selection under the declared configuration. In one embodiment, the prime set 302 is a fixed ordered list of primes stored in memory and indexed by rank, and a prime identifier is the rank into that list. In another embodiment, the prime set 302 is generated by a deterministic prime-generation procedure that produces primes in a fixed order, and a prime identifier is an index into that generated sequence. In one embodiment, the prime set 302 is bounded by a maximum prime derived from sampling and mapping constraints so that candidate center frequencies do not exceed a declared limit, and the bound is reproducible given the same configuration.

A prime selector 304 determines which primes from the prime set 302 are evaluated for a given processing unit. In one embodiment, the prime selector 304 enumerates all primes up to a bound in increasing order. In another embodiment, the prime selector 304 enumerates a deterministic subset of primes according to a declared profile rule, such as a fixed prime band selection or a fixed interleaving rule, provided that the same rule is used whenever that profile is selected. In one embodiment, the prime selector 304 uses a deterministic candidate ordering that is independent of input content so that ordering is not content-dependent.

A center set 306 provides permissible center identifiers for atoms within a processing unit. In one embodiment for one-dimensional blocks, the center set 306 includes center identifiers that map to integer sample indices n0 within the block according to a declared stride rule. In one embodiment for two-dimensional tiles, the center set 306 includes center identifiers that map to integer pixel coordinates within the tile, and the mapping rule is declared. In one embodiment, the center set 306 is defined so that centers form a regular grid, and in another embodiment the center set 306 includes additional boundary centers under a deterministic rule to improve representation near tile or block boundaries.

A stride parameter 308 defines a deterministic spacing between consecutive permissible center positions for one-dimensional blocks. In one embodiment, the stride parameter 308 is a deterministic function of block size N, and the stride parameter 308 yields a fixed number of permissible centers per block. In one embodiment, the stride parameter 308 is selected so that the number of permissible centers is a power of two, and in another embodiment the number is selected to match a declared coding convenience, provided that the mapping is fixed by profile. A variant selector 310 provides optional discrete variants that expand the dictionary with a finite, addressable set of atom variants. In one embodiment, the variant selector 310 enables a phase variant identifier that selects among a finite set of discrete phase offsets for the oscillatory term of an atom, such as 0 and pi/2, where the phase set is declared and fixed. In one embodiment, the variant selector 310 enables a sign variant identifier that indicates whether a coefficient sign is carried explicitly or whether sign is encoded as part of a variant. In one embodiment, the variant selector 310 enables a scale variant identifier that selects among a finite set of envelope widths or envelope scalings, where each scale variant corresponds to a deterministic adjustment of sigma produced by the mapping rules. In each case, the variant selector 310 restricts variants to discrete identifiers so that regeneration is exact under the declared rule.

An address generator 312 maps a tuple of identifiers to an address that selects parameters and/or waveform resources for a candidate atom. In one embodiment, the address generator 312 maps (prime identifier, center identifier, variant identifier) into a linear address by concatenating fixed-width bit fields whose widths are determined by declared bounds on primes, centers, and variants. In another embodiment, the address generator 312 maps the tuple through a deterministic hash or table-lookup mapping that is fixed by profile. In one embodiment, the address generator 312 is designed so that two different tuples cannot map to the same address within a declared profile, thereby avoiding aliasing that could cause ambiguity. A parameter table 314 stores atom-generation parameters that can be fetched by address to regenerate atoms without storing full waveforms. In one embodiment, the parameter table 314 stores per-prime parameters including a per-prime angular frequency increment used for discrete-time cosine evaluation. In one embodiment, the parameter table 314 stores per-prime normalization factors used to normalize atoms or to scale coefficients deterministically. In one embodiment, the parameter table 314 stores per-variant parameters that modify envelope width or phase according to the variant identifier. In one embodiment, the parameter table 314 stores a per-profile constant set identifier so that the same table is not misinterpreted under a different profile.

A waveform generator 316 regenerates atom values from parameters in a deterministic arithmetic domain. In one embodiment, the waveform generator 316 generates a Gaussian envelope value as a deterministic function of an index offset (n−n0) and a width sigma, using either fixed-point arithmetic or a lookup table with declared interpolation rules. In one embodiment, the waveform generator 316 generates an oscillatory term using a deterministic cosine evaluation, including using a precomputed cosine table indexed by a phase accumulator derived deterministically from prime identifier and sample index. In one embodiment, the waveform generator 316 multiplies the envelope and oscillatory terms and applies normalization and scaling according to the parameter table 314, producing an atom sample sequence aligned to the processing unit index domain.

A waveform table 318 optionally stores waveform resources for deterministic lookup. In one embodiment, the waveform table 318 stores a finite set of envelope shapes indexed by width and a finite set of oscillatory sequences indexed by prime identifier, and the waveform generator 316 combines them to form atom samples. In one embodiment, the waveform table 318 stores complete atom waveforms for a subset of primes and centers to accelerate correlation computation in hardware, and missing waveforms are generated procedurally. In one embodiment, the waveform table 318 stores compressed waveform representations that can be expanded deterministically under a declared decode rule.

A candidate atom output 320 provides candidate atoms or candidate atom descriptors for evaluation. In one embodiment, the candidate atom output 320 provides full atom sample sequences for correlation evaluation. In another embodiment, the candidate atom output 320 provides a descriptor sufficient for an inner-product engine to evaluate correlations using a procedural atom generator on-the-fly. In one embodiment, the candidate atom output 320 provides candidates in a deterministic order defined by the prime selector 304, the center set 306 ordering, and the variant selector 310 ordering.

A coherence evaluator 322 can compute dictionary diagnostics used for monitoring and configuration validation. In one embodiment, the coherence evaluator 322 computes pairwise correlation bounds for a subset of atoms to confirm that dictionary configuration is consistent with expected sparsity behavior. In one embodiment, the coherence evaluator 322 computes aggregate statistics such as maximum observed correlation among a sample of candidate pairs. In one embodiment, the coherence evaluator 322 operates as a diagnostic function and does not alter deterministic decoding behavior, and any use of its outputs for configuration selection is performed only under declared profile rules that remain deterministic.

A selected atom descriptor output 324 provides atom identifiers that are recorded in the spike list and later used for regeneration. In one embodiment, the selected atom descriptor output 324 includes a prime identifier and a center identifier and includes a variant identifier when variants are enabled. In one embodiment, the selected atom descriptor output 324 is encoded in a compact fixed-width structure to facilitate entropy coding. In one embodiment, the selected atom descriptor output 324 is encoded in a variable-length structure whose parse is unambiguous because a spike count is known and each field is self-delimiting under declared coding rules. A one-dimensional atom used by the dictionary subsystem 300 can be defined in discrete-time form so that its evaluation is deterministic on a sample grid. In one embodiment, an atom is evaluated at integer index n with center index n0 using an envelope term exp(−((n−n0)\hat{ }2)/(2sigma\hat{ }2)) where sigma is a width in samples and the exponential evaluation is performed in a declared numeric domain, and using an oscillatory term cos(2*pi p f0 (n/F_s)+phi_var) where p is a prime number and phi_var is a discrete phase variant when enabled. In one embodiment, the center frequency associated with prime p is f_p=p*f0, and p is bounded by a deterministic constraint derived from the sampling configuration so that f_p does not exceed a declared limit.

A dictionary profile can be defined so that both encoder and decoder interpret identifiers consistently. In one embodiment, the profile defines the ordered prime set 302, the center set 306 mapping rule, the stride parameter 308 rule when used, the enabled variants supported by the variant selector 310, the address mapping used by the address generator 312, and the parameter interpretation rules for the parameter table 314. In that embodiment, a decoder that supports the profile can regenerate atoms referenced by prime and center identifiers without receiving per-atom waveform payloads, reducing bitstream size while preserving deterministic reconstruction. A sparse decomposition engine 400 produces a spike list and a residual for each processing unit by iteratively selecting atoms from the dictionary and updating a residual according to deterministic selection and update rules. The sparse decomposition engine 400 operates under a declared mode that determines termination rules and residual coding policy, and the sparse decomposition engine 400 produces outputs that are suitable for deterministic entropy coding and deterministic reconstruction.

An input unit buffer 402 holds a processing unit to be encoded. In one embodiment, the input unit buffer 402 stores integer samples or integer pixels in a canonical internal representation. In one embodiment, the input unit buffer 402 stores multiple channels for a processing unit, or stores a transformed representation of multiple channels under a reversible transform that is declared for the profile.

A residual buffer 404 holds a current residual associated with the processing unit. In one embodiment, the residual buffer 404 is initialized to the processing unit. In another embodiment, the residual buffer 404 is initialized to a pre-processed version of the processing unit, such as a windowed block for audio or a pre-filtered tile for image/video, provided that the pre-processing is deterministic and declared. In one embodiment, the residual buffer 404 stores values in an internal numeric domain that can be fixed-point or floating-point, and in lossless mode a separate integer-domain residual is ultimately formed and coded exactly to guarantee exact reconstruction.

An atom fetch interface 406 supplies candidate atoms or candidate atom descriptors from the dictionary subsystem for evaluation against the residual. In one embodiment, the atom fetch interface 406 enumerates candidates in the deterministic ordering defined by prime ordering, center ordering, and variant ordering. In one embodiment, the atom fetch interface 406 supports partial enumeration so that candidates can be evaluated in bands while maintaining deterministic selection behavior under declared tie-breaking rules.

An inner-product engine 408 computes correlation values between the current residual and candidate atoms. In one embodiment, the inner-product engine 408 computes an inner product as a sum of products over a defined index set for the processing unit, and the sum is computed in a declared numeric domain with declared rounding and saturation rules. In one embodiment, the inner-product engine 408 applies a deterministic normalization so that correlation values are comparable across candidates. In one embodiment, the inner-product engine 408 can be implemented using vector instructions, GPU kernels, FPGA pipelines, or ASIC logic, provided that any reduction ordering or rounding is consistent with the declared numeric domain rules. An argmax selector 410 selects a candidate atom that maximizes a declared objective metric. In one embodiment, the objective metric is the absolute value of the correlation magnitude |<r_n, g>|. In another embodiment, the objective metric includes a deterministic penalty term that discourages selection of candidates that are too close in center identifier to a previously selected spike, provided that the penalty rule is declared and depends only on already known spike list entries and not on future content. In one embodiment, the argmax selector 410 applies a deterministic tie-breaking rule when candidates compare equal under the declared compare rule. A coefficient extractor 412 computes a coefficient value for the selected atom. In one embodiment, the coefficient extractor 412 computes the coefficient as the inner product a_n=<r_n, g_selected> under a declared normalization of g_selected. In another embodiment, the coefficient extractor 412 computes a scaled coefficient that accounts for atom energy or a normalization factor obtained from the parameter table. In one embodiment, the coefficient extractor 412 represents coefficients in a declared coefficient domain, including fixed-point representation with declared scaling. In one embodiment, coefficient extraction includes a deterministic saturation rule to avoid overflow, and any saturation behavior is declared by profile.

A spike-list builder 414 appends an entry to a spike list data structure. In one embodiment, each spike entry includes a prime identifier, a center identifier, an optional variant identifier, and a coefficient value, and entries are appended in selection order. In another embodiment, spike entries are appended in selection order and then optionally sorted in a deterministic manner prior to coding, provided that the sorting rule is declared. In one embodiment, the spike-list builder 414 maintains a spike count and maintains any per-unit scaling fields used for interpreting coefficients.

A residual updater 416 updates the residual using the selected atom and coefficient. In one embodiment, the residual updater 416 computes r_{n+1}=r_n−a_n*g_selected and stores the result in the residual buffer 404. In one embodiment, the subtraction is performed in the internal numeric domain with declared rounding and saturation. In one embodiment, if the internal numeric domain is fixed-point, the residual updater 416 uses a declared scaling alignment rule so that a_n*g_selected is aligned to the residual representation before subtraction. In one embodiment, if the internal numeric domain is floating-point, the residual updater 416 uses a declared precision and a declared operation ordering.

An iteration controller 418 governs the iteration loop used to build the spike list. In one embodiment, the iteration controller 418 initializes an iteration counter to zero and increments it for each selected spike. In one embodiment, the iteration controller 418 enforces a maximum spike budget k_max declared by profile. In one embodiment, the iteration controller 418 enforces a minimum spike magnitude threshold so that if the magnitude of a selected coefficient is below the threshold, no spike is recorded and termination occurs under a declared rule.

A near-lossless evaluator 420 computes an objective residual metric used for termination in near-lossless mode. In one embodiment, the near-lossless evaluator 420 computes a residual energy ratio defined as ||r||\hat{ }2/||x||\hat{ }2 using a declared energy computation rule, where ||.||\hat{ }2 is computed as a sum of squares in a declared numeric domain. In another embodiment, the near-lossless evaluator 420 computes a maximum absolute error metric defined as max_i|e_i| where e_i is a per-sample or per-pixel error between a current approximation and the original, and the maximum is computed deterministically. In one embodiment, the near-lossless evaluator 420 compares the metric to a declared threshold epsilon that is signaled or implied by profile. A spike-budget evaluator 422 evaluates whether the number of selected spikes has reached a declared budget. In one embodiment, the spike-budget evaluator 422 compares the iteration count to a declared k_max and signals when the budget is reached. In one embodiment, the spike-budget evaluator 422 also supports a mode-specific budget, including a smaller budget for lossy mode and a larger budget for lossless mode, as declared by profile.

A termination controller 424 decides whether to continue selecting spikes or to terminate and hand off to residual coding. In one embodiment, the termination controller 424 terminates when the spike budget is reached in lossless mode and near-lossless mode. In one embodiment, the termination controller 424 terminates in near-lossless mode when the residual metric satisfies the declared criterion. In one embodiment, the termination controller 424 terminates in lossy mode when a lossy spike budget is reached, regardless of residual metric. In one embodiment, the termination controller 424 applies deterministic priority among termination conditions, such as checking for coefficient threshold termination first, then checking for residual metric satisfaction, then checking for budget exhaustion, where the priority order is declared.

A residual output interface 426 outputs residual information for subsequent coding. In one embodiment, the residual output interface 426 outputs the residual buffer contents in the internal numeric domain for further processing. In one lossless embodiment, the residual output interface 426 outputs an integer-domain residual r_int defined as the exact integer difference between the original integer processing unit and an integer-domain mapping of the current approximation, and the residual coder encodes r_int exactly. In one embodiment, the integer-domain mapping is a deterministic rounding or quantization rule declared by profile, and the same rule is applied by a decoder when combining sparse component and residual to reconstruct the original integers. A deterministic candidate ordering and tie-breaking rule is used to ensure reproducible selection behavior. In one embodiment, candidate atoms are ordered by increasing prime identifier, then increasing center identifier, and then increasing variant identifier when variants are enabled, and when two candidates have equal objective metric value under a declared compare rule, the earlier candidate in that ordering is selected. In one embodiment, the compare rule is exact equality in fixed-point. In another embodiment, for near-lossless or lossy operation, the compare rule uses a declared tolerance and treats values within the tolerance as equal.

A selection/update equation family can be used to describe matching pursuit behavior in one embodiment without limiting other deterministic sparse selection procedures. In one embodiment, the argmax selector 410 selects (p*, c*) that maximizes |<r_n, g_{p,c}>| over eligible primes p and centers c, the coefficient extractor 412 computes a_n=<r_n, g_{p*, c*}>, and the residual updater 416 computes r_{n+1}=r_n−a_n*g_{p*, c*}. In another embodiment, a deterministic orthogonalization step is performed to reduce correlation among selected atoms, provided that the orthogonalization procedure is declared and reproducible. In another embodiment, a deterministic re-optimization step updates coefficients of prior spikes after selecting a new spike, provided that the update rule depends only on already selected spikes and is deterministic.

A practical termination design is provided for lossless mode in which the spike list is used to capture structured content while the residual is used to guarantee exact reconstruction. In one embodiment, the iteration controller 418 enforces a fixed k_max and the residual output interface 426 outputs the final integer-domain residual, and the residual coder encodes that residual exactly, yielding bit-perfect reconstruction at the decoder. In another embodiment, a near-lossless criterion is also evaluated and when satisfied before reaching k_max the engine terminates early and residual coding proceeds accordingly.

The sparse decomposition engine 400 can be configured to support streaming and low-latency operation by using a fixed block size and a fixed maximum spike count such that compute is bounded per block. In one embodiment, the sparse decomposition engine 400 uses a deterministic per-block time budget and if the time budget is reached, termination occurs under a declared rule that preserves deterministic behavior, such as terminating at the current spike count and coding the remaining residual under the declared mode.

An entropy coding subsystem 500 converts spike list entries and residual information into a compressed payload that can be parsed deterministically and decoded to reproduce the spike list and residual. The entropy coding subsystem 500 supports multiple coding choices for primes, centers, coefficients, and residuals, provided that each choice is declared by configuration or implied by a declared profile and is interpreted consistently by the decoder.

A spike-list input buffer 502 receives spike list entries produced by sparse decomposition for a processing unit. In one embodiment, the spike-list input buffer 502 stores spike entries in selection order. In another embodiment, the spike-list input buffer 502 stores spike entries after a deterministic reordering step, such as sorting by prime identifier and then by center identifier. In one embodiment, the spike-list input buffer 502 stores a spike count indicating the number of entries for the processing unit and stores any per-unit metadata needed to interpret coefficient scaling. A prime-index coder 504 encodes prime identifiers associated with spike entries. In one embodiment, a prime identifier is a rank into an ordered prime list, and the prime-index coder 504 encodes ranks using Golomb-Rice coding with a parameter value that is fixed by profile or signaled as configuration. In one embodiment, the prime-index coder 504 encodes differences between successive prime ranks when spike entries are ordered by prime rank, reducing coded size when ranks cluster. In another embodiment, the prime-index coder 504 encodes prime identifiers using arithmetic coding or range coding with a model updated deterministically from previously coded prime identifiers. In each case, the coding method is declared and the mapping between coded values and prime identifiers is unambiguous. A center coder 506 encodes center identifiers associated with spike entries. In one embodiment, a center identifier is an index into a center grid of fixed size for a given processing unit, and the center coder 506 encodes center identifiers using fixed-length codes derived from the grid size. In another embodiment, the center coder 506 encodes center identifiers using entropy coding based on a deterministic distribution model. In one embodiment, when spike entries are ordered by center, the center coder 506 encodes deltas between successive center identifiers to exploit local clustering. In one embodiment, center identifiers for two-dimensional tiles include an axis identifier or separate axis identifiers, and the center coder 506 encodes axis components under declared rules. A coefficient coder 508 encodes coefficient values associated with spike entries. In one embodiment, coefficients are represented as signed fixed-point integers with a declared scaling exponent, and the coefficient coder 508 encodes magnitudes and signs using arithmetic coding or range coding with a deterministic model. In one embodiment, the coefficient coder 508 uses a Laplacian-like magnitude model whose scale parameter is updated deterministically from previously coded coefficients. In one embodiment, the coefficient coder 508 uses context selection that depends only on decoded fields such as prime bands or center bands, with context definitions declared by profile. In another embodiment, the coefficient coder 508 encodes coefficients using Rice codes or another prefix code family after mapping coefficients to nonnegative integers in a declared manner. In each embodiment, coefficient decoding is invertible and deterministic. A residual predictor 510 optionally predicts residual values prior to entropy coding of residual information. In one embodiment, the residual predictor 510 is disabled and residual values are coded directly. In one embodiment, the residual predictor 510 is enabled and uses a fixed predictor order and fixed predictor coefficients defined by profile for one-dimensional signals. In one embodiment for audio, the residual predictor 510 uses a fixed linear predictor that predicts a sample from a fixed set of previous samples, and boundary handling at the start of a block is deterministic. In one embodiment for images and video, the residual predictor 510 uses a spatial predictor that predicts a pixel from neighboring pixels within the tile, and boundary handling at tile edges is deterministic. In one embodiment, the residual predictor 510 uses a reversible integer predictor so that the difference between actual and predicted values is an integer prediction error that can be coded exactly. A prediction error generator 512 computes prediction errors when residual prediction is enabled. In one embodiment, the prediction error generator 512 computes an integer error e=r−pred(r) for each residual value r and predicted value pred(r) in a declared integer domain. In one embodiment, the prediction error generator 512 applies a deterministic mapping of signed errors to nonnegative integers for coding, such as a signed-to-unsigned bijection defined by profile. In one embodiment, the prediction error generator 512 supports run-length coding of repeated errors, such as sequences of zeros, under a declared rule. A residual entropy coder 514 encodes residual information. In one lossless embodiment, the residual entropy coder 514 encodes residual values or prediction errors exactly so that the decoder reproduces the same integers, and exact reconstruction is obtained when combining the decoded residual with the decoded sparse component under the declared reconstruction rule. In one near-lossless embodiment, the residual entropy coder 514 encodes residual information under a declared reduced-precision rule, such as truncating low-order bits or quantizing residual values to a declared step size, and the reduced-precision rule is declared so the decoder applies the same inverse interpretation. In one lossy embodiment, the residual entropy coder 514 omits residual coding or encodes only a reduced residual representation under a declared policy. A header generator 516 produces configuration fields that enable deterministic decoding. In one embodiment, header fields include a mode indicator, a representation indicator for coefficient and residual domains, a dictionary configuration identifier, a center-grid identifier, and a residual coder configuration identifier. In one embodiment, header fields include block size and hop size for audio and tile size and plane configuration for image/video, when such parameters are not implied by a fixed profile. In one embodiment, header fields include integrity fields such as a checksum for a processing unit record, and checksum computation and verification are deterministic. A mode field 518 indicates an operating mode for a stream or for a processing unit. In one embodiment, the mode field 518 indicates lossless mode and implies that a residual payload is present and coded exactly. In one embodiment, the mode field 518 indicates near-lossless mode and implies that a distortion criterion and a residual policy are active. In one embodiment, the mode field 518 indicates lossy mode and implies that a truncation policy and residual policy are active. In one embodiment, mode parameters such as a spike budget or a distortion threshold are included as additional fields or are implied by profile. A dictionary field 520 indicates dictionary configuration. In one embodiment, the dictionary field 520 identifies a prime list rule, a prime bound rule, enabled discrete variants, and atom-generation parameter mapping identifiers. In one embodiment, the dictionary field 520 indicates whether a dictionary is fully procedural, table-assisted, or waveform-assisted, and the decoder uses the field to select the appropriate regeneration method. In one embodiment, the dictionary field 520 indicates whether adaptive supplementary atoms are present and, if present, indicates how they are represented in the stream. A predictor field 522 indicates residual predictor configuration when residual prediction is used. In one embodiment, the predictor field 522 indicates a predictor type identifier and a predictor order. In one embodiment, for image and video predictors, the predictor field 522 indicates which neighboring samples are used and how boundaries are handled. In one embodiment, predictor configuration is fixed by profile and predictor field 522 is omitted. A spike-list field 524 contains encoded spike list payload data. In one embodiment, spike-list field 524 includes a spike count and then includes encoded sequences for prime identifiers, center identifiers, and coefficients, where sequences are interleaved or separately coded according to a declared scheme. In one embodiment, prime identifiers, center identifiers, and coefficients are interleaved per spike entry. In another embodiment, all prime identifiers are coded first, then all center identifiers, then all coefficients, and the decoder reconstructs spike entries by combining decoded sequences in the declared order.

A residual field 526 contains encoded residual payload data. In one embodiment, residual field 526 contains coded residual values or coded prediction errors for lossless mode. In one embodiment, residual field 526 contains reduced-precision residual information in near-lossless mode. In one embodiment, residual field 526 is absent in a lossy mode when residual is omitted by policy. In one embodiment, residual field 526 includes a length indicator so that the decoder can skip or validate the residual payload.

A formatter 528 assembles fields into a compressed payload. In one embodiment, the formatter 528 constructs a processing unit record including the mode field 518, dictionary field 520, predictor field 522 where present, spike-list field 524, residual field 526 where present, and any integrity field, and places the record into the stream. In one embodiment, the formatter 528 aligns records to byte boundaries and includes explicit lengths for variable-length payload sections. In another embodiment, the formatter 528 uses self-delimiting codes and the record boundary is determined by decoding the known number of spike entries and the known length of residual payload.

A compressed payload output 530 outputs the compressed payload to storage or transport. In one embodiment, the compressed payload output 530 outputs to a file container that also stores metadata such as sampling rate, channel count, frame size, and color space. In one embodiment, the compressed payload output 530 outputs to a packetized transport format in which records can be sent independently, and record integrity fields support detection of packet corruption.

A coding design is provided in which the spike list captures structured components efficiently and the residual coding completes reconstruction with exactness in lossless mode. In one embodiment, entropy coding is configured so that prime identifiers and center identifiers are coded with low overhead and coefficients are coded with distribution-aware coding, while residual coding is configured to exploit predictability and produce exact reconstruction. In one embodiment, coding tables and model update rules are fixed by profile to maintain deterministic decoder behavior across platforms.

A decoder subsystem 600 reconstructs a processing unit by parsing a compressed payload, decoding a spike list and residual information, regenerating atoms corresponding to decoded spike entries, forming a sparse component by accumulating regenerated atoms weighted by decoded coefficients, and combining the sparse component with a decoded residual under a declared reconstruction rule. The decoder subsystem 600 produces reconstructed output values in the representation domain corresponding to the selected mode.

A compressed payload input 602 receives a compressed payload containing records that correspond to processing units. In one embodiment, the compressed payload input 602 receives a byte stream from a file container. In another embodiment, the compressed payload input 602 receives packetized records from a network transport. In one embodiment, the compressed payload input 602 supports resynchronization using markers or restart points embedded in the stream.

A header parser 604 parses configuration fields and validates that the stream is decodable under supported configurations. In one embodiment, the header parser 604 parses a version identifier and a profile identifier and validates that the profile is supported. In one embodiment, the header parser 604 parses configuration parameters such as sampling rate, channel count, bit depth, block size, hop size, stride, frame dimensions, tile dimensions, and plane configuration, when such parameters are present. In one embodiment, the header parser 604 parses a mode indicator for the stream or for each record and configures downstream decoding accordingly. In one embodiment, the header parser 604 validates field ranges and record lengths and rejects malformed records rather than producing undefined outputs.

A spike-list decoder 606 decodes spike list payload data into spike entries including prime identifiers, center identifiers, optional variant identifiers, and coefficients. In one embodiment, the spike-list decoder 606 decodes a spike count first and then decodes sequences of prime identifiers, center identifiers, and coefficients according to the declared coding scheme. In one embodiment, spike entries are decoded in the same order used for encoding, and in another embodiment spike entries are reconstructed from separately decoded sequences in a declared order. In one embodiment, the spike-list decoder 606 validates that decoded identifiers are within declared bounds for the current configuration.

A residual decoder 608 decodes residual payload data. In one lossless embodiment, the residual decoder 608 decodes residual values or prediction errors exactly in an integer domain so that decoded residual values match encoded residual values exactly. In one embodiment, when residual prediction is enabled, the residual decoder 608 applies the same predictor configuration that was used by the encoder and reconstructs residual values from decoded prediction errors using deterministic boundary handling. In one near-lossless embodiment, the residual decoder 608 decodes reduced-precision residual information and reconstructs a residual under the declared reduced-precision interpretation rule. In one lossy embodiment, residual payload may be absent and the residual decoder 608 outputs a defined default residual, such as an all-zero residual, under the declared policy.

A dictionary regenerator 610 provides atom-generation configuration for decoding. In one embodiment, the dictionary regenerator 610 regenerates dictionary parameters from a dictionary configuration identifier and from configuration values such as sampling rate and processing-unit size using shared deterministic mapping rules. In one embodiment, the dictionary regenerator 610 provides a prime set and a center grid consistent with the current record configuration. In one embodiment, when supplementary atoms are present, the dictionary regenerator 610 reconstructs supplementary atom parameters from a signaled table using deterministic interpretation rules.

An atom regenerator 612 regenerates atoms referenced by decoded spike entries. In one embodiment, the atom regenerator 612 uses a prime identifier, a center identifier, and an optional variant identifier to generate an atom sample sequence aligned to the processing unit index domain. In one embodiment, atom regeneration uses fixed-point arithmetic with declared scaling. In another embodiment, atom regeneration uses floating-point arithmetic with declared precision. In one embodiment, atom regeneration uses lookup tables for Gaussian envelope values and cosine values, and table indexing and interpolation rules are deterministic. In one embodiment, atom regeneration applies normalization factors obtained from a parameter table.

A spike accumulator 614 forms a sparse component by accumulating regenerated atoms weighted by decoded coefficients. In one embodiment, for each decoded spike entry, the spike accumulator 614 multiplies the regenerated atom by the decoded coefficient and adds the result to an accumulator buffer for the processing unit. In one embodiment, accumulation is performed in an internal numeric domain with declared rounding and saturation. In one embodiment, accumulation is performed in a higher precision domain than the final output domain and then mapped to an output domain under a declared mapping rule. In one embodiment, accumulation is performed using a deterministic operation ordering so that results are reproducible.

A residual combiner 616 combines the sparse component with the decoded residual to form a reconstructed processing unit. In one lossless embodiment, the residual combiner 616 applies a declared mapping rule to map the sparse component into an integer reconstruction domain and then adds the decoded integer-domain residual to produce integer reconstructed output values that match the original input values exactly. In one embodiment, the mapping rule is a deterministic rounding rule applied elementwise. In one embodiment, the residual combiner 616 applies a deterministic saturation rule when adding values to avoid overflow and uses the same saturation rule that was assumed when defining the residual at the encoder. In one near-lossless embodiment, the residual combiner 616 combines a sparse component with a reduced-precision residual under a declared rule, producing output that satisfies the declared distortion criterion. In one lossy embodiment, the residual combiner 616 outputs the sparse component alone or outputs the sparse component plus a reduced residual, depending on the declared policy.

An overlap/assembly engine 618 assembles reconstructed processing units into an output signal. In one audio embodiment, the overlap/assembly engine 618 performs overlap-add reconstruction for overlapped blocks under a declared hop size and declared windowing rules, and the overlap/assembly engine 618 produces a continuous output sample stream. In one embodiment, the overlap/assembly engine 618 uses an analysis/synthesis window pair with deterministic values and deterministic normalization, and boundary handling at the beginning and end of a stream is deterministic. In one image or video embodiment, the overlap/assembly engine 618 assembles tiles into planes and planes into frames under a declared tile traversal order and declared placement rules. In one embodiment, the overlap/assembly engine 618 recombines luma and chroma planes and applies a deterministic color-space conversion when output is required in a different color space than the coded space. In one medical imaging embodiment, the overlap/assembly engine 618 assembles tiles into slices and slices into a sequence under a deterministic slice ordering.

A reconstructed unit output 620 provides reconstructed processing units for further processing or verification. In one embodiment, reconstructed unit output 620 is used by an integrity checker to compute per-unit hashes or checksums. In one embodiment, reconstructed unit output 620 is provided to a renderer or playback pipeline. In one embodiment, reconstructed unit output 620 is stored for later assembly.

A reconstructed signal output 622 provides the reconstructed output signal. In one embodiment, reconstructed signal output 622 outputs PCM samples for audio. In one embodiment, reconstructed signal output 622 outputs frames for video. In one embodiment, reconstructed signal output 622 outputs slices for medical imaging. In one embodiment, reconstructed signal output 622 outputs telemetry values for telemetry streams.

Decoder validation and failure handling: In one embodiment, the header parser 604 validates that decoded identifiers and decoded payload lengths are within permitted bounds for the declared profile and configuration, and if validation fails the decoder rejects the record or signals an error rather than producing a reconstructed unit with unknown correctness. In one embodiment, when integrity fields are present, the decoder verifies them and discards corrupted records. In one embodiment, when resynchronization markers are present, the decoder can skip corrupted portions and resume decoding at the next marker under a deterministic rule.

Deterministic reconstruction across platforms: In one embodiment, deterministic reconstruction is ensured by using fixed-point arithmetic and fixed operation ordering for atom regeneration and accumulation. In another embodiment, deterministic reconstruction is ensured by defining residuals in the integer output domain and coding those residuals exactly, so that any small variation in intermediate floating-point computations does not prevent bit-perfect output in lossless mode. In each case, reconstruction is defined by the combination of decoded spike list semantics, atom regeneration rules, accumulation rules, and residual combination rules.

An audio processing embodiment 700 is provided in which one-dimensional sample sequences are encoded and decoded using overlapped blocks, sparse decomposition in a prime-indexed Gaussian-spike dictionary, and residual coding suitable for exact reconstruction or objective distortion control. Audio embodiments support mono, stereo, and multi-channel configurations and can apply reversible channel transforms prior to sparse decomposition to reduce redundancy while preserving reconstructability.

An audio source 702 provides audio samples to a channel handler 704. In one embodiment, the audio source 702 provides integer PCM samples in a signed representation. In one embodiment, the audio source 702 provides samples for multiple channels. In one embodiment, the audio source 702 provides samples in a container that includes metadata such as sample rate and bit depth, and the decoder uses the metadata or corresponding stream fields to interpret reconstructed output.

A channel handler 704 prepares channels for block processing. In one embodiment, the channel handler 704 passes channels through unchanged and the codec encodes each channel independently under the same profile. In one embodiment, the channel handler 704 applies a reversible stereo transform that maps left and right channels to a mid channel and a side channel using integer arithmetic with a declared rounding rule, and the inverse transform is applied after reconstruction. In one embodiment, the channel handler 704 applies a reversible difference-channel transform in which one channel is treated as a reference channel and one or more other channels are represented as integer differences relative to the reference, and the inverse transform reconstructs the original channels exactly in lossless mode. In one embodiment, the channel handler 704 applies a reversible group transform in which channels are partitioned into groups and differences are computed within groups, and grouping rules are declared.

A frame buffer 706 stores audio samples for block formation and overlap operation. In one embodiment, the frame buffer 706 stores a sliding window of samples that includes the current block and any required overlap region. In one embodiment, the frame buffer 706 stores samples for multiple channels or transformed channels. In one embodiment, the frame buffer 706 supports streaming operation by maintaining a bounded buffer and producing blocks as new samples arrive, where buffering rules are deterministic.

A windowing stage 708 applies an analysis window to a block prior to sparse decomposition when windowing is enabled. In one embodiment, the analysis window is selected from a declared set of window functions and the selected window is defined by deterministic coefficients. In one embodiment, windowing is disabled and block boundaries are handled by a declared stitching rule. In one embodiment, when windowing is enabled, a synthesis window is used at reconstruction such that overlap-add produces a defined combined response, and window coefficients and normalization rules are deterministic.

A hop controller 710 advances block formation according to a hop size. In one embodiment, the hop controller 710 uses a hop size that is a deterministic fraction of the block length N, such as N/4, and thus produces overlapped blocks with a deterministic overlap region. In one embodiment, the hop controller 710 uses a hop size equal to N for non-overlapped blocks. In one embodiment, the hop controller 710 supports low-latency operation by selecting a smaller N and corresponding hop size under a declared profile.

A center grid 712 defines permissible atom centers within each audio block. In one embodiment, the center grid 712 defines center identifiers mapped to integer sample indices within the block using a stride rule that is a deterministic function of N. In one embodiment, the center grid 712 provides center identifiers at regular intervals and optionally provides boundary centers under a deterministic rule. In one embodiment, the center grid 712 provides center identifiers that are shared across channels when channels are processed independently, and in another embodiment provides per-channel center grids when channel-specific grids are enabled.

A spike-list generator 714 performs sparse decomposition of an audio block and outputs spike entries. In one embodiment, the spike-list generator 714 invokes the sparse decomposition engine and produces prime identifiers, center identifiers, and coefficients for selected atoms and produces a residual for the block. In one embodiment, the spike-list generator 714 uses a lossless mode policy that limits spike selection to a declared budget and relies on exact residual coding to guarantee bit-perfect reconstruction. In one embodiment, the spike-list generator 714 uses a near-lossless policy that terminates when an objective residual criterion is satisfied. In one embodiment, the spike-list generator 714 uses a lossy policy that truncates spike selection and omits or reduces residual coding under a declared rule.

A residual output 716 provides residual information for residual coding. In one lossless embodiment, the residual output 716 provides integer-domain residual values defined so that the decoder reconstructs original integer PCM values exactly when combining the mapped sparse component and the decoded residual. In one embodiment, the residual output 716 provides a residual that is further processed by a predictor for entropy coding, provided that the predictor is reversible and declared. In near-lossless embodiments, the residual output 716 provides reduced-precision residual values under a declared rule.

An audio reconstruction stage 718 reconstructs audio blocks from decoded spike lists and decoded residuals. In one embodiment, the audio reconstruction stage 718 regenerates atoms referenced by decoded spike entries, accumulates atoms weighted by decoded coefficients to form a sparse component, maps the sparse component into an integer domain under a declared rule, and adds the decoded integer residual to obtain reconstructed integer samples in lossless mode. In one embodiment, the audio reconstruction stage 718 performs overlap-add using the synthesis window and hop size, producing reconstructed output samples. In one embodiment, the audio reconstruction stage 718 applies an inverse channel transform after overlap-add when a reversible channel transform was applied prior to encoding.

An audio output stream 720 outputs reconstructed samples. In one embodiment, the audio output stream 720 outputs reconstructed integer PCM values. In one embodiment, the audio output stream 720 outputs a multi-channel stream. In one embodiment, the audio output stream 720 outputs a stream in the same container format and metadata configuration as the input, with reconstructed samples replacing original samples. In one embodiment, the audio output stream 720 is provided to a playback pipeline or to a file writer.

A sink 722 receives the audio output stream. In one embodiment, the sink 722 is a storage sink that writes a decoded file. In one embodiment, the sink 722 is a network sink that transmits decoded audio. In one embodiment, the sink 722 is a playback sink that provides decoded audio to a digital-to-analog converter pipeline.

Concrete audio configuration examples are supported as selectable profiles. In one embodiment, a block length N is 2048 samples and the hop size is N/4, and a center stride is selected as a deterministic fraction of N, and coefficients are represented in a fixed-point domain with a declared bit width. In one embodiment, the profile supports 16-bit audio and 24-bit audio by selecting appropriate residual coding and coefficient mapping rules. In one embodiment, the profile supports sample rates including 44.1 kHz and 96 kHz by mapping normalized parameters to the sampling grid using the sample rate and block length.

Silence and low-structure handling in audio blocks is deterministic. In one embodiment, when a block contains near-silence, the spike-list generator 714 records zero spikes under a declared coefficient threshold rule and residual coding represents the block efficiently using prediction. In one embodiment, when a block contains strong transients, the spike-list generator 714 uses available spike budget to represent transient structure and residual coding completes reconstruction. In one embodiment, per-block decisions regarding spike budget use are made under a declared rule that does not depend on subjective tuning.

Streaming and bounded-latency audio operation is supported by deterministic buffering and bounded per-block compute. In one embodiment, the frame buffer 706 holds a bounded number of samples and the hop controller 710 advances blocks with no more than a fixed look-ahead. In one embodiment, per-block compute is bounded by a declared maximum number of spikes and a declared candidate enumeration scope, and if a time budget limit is enforced, termination occurs under a declared rule and residual coding completes reconstruction as required by the selected mode.

A video and image processing embodiment 800 is provided in which two-dimensional planes are encoded and decoded using tile partitioning, sparse decomposition in a prime-indexed Gaussian-spike basis extended to two dimensions, and residual coding suitable for exact reconstruction or objective distortion control. Video embodiments support multiple color representations including RGB and YUV and support per-plane processing with deterministic plane handling and deterministic tile traversal.

A video source 802 provides frames to a color-space converter 804. In one embodiment, the video source 802 provides frames in RGB with integer component values. In one embodiment, the video source 802 provides frames in YUV with luma and chroma planes. In one embodiment, the video source 802 provides still images treated as single-frame video sequences. In one embodiment, the video source 802 provides medical images as frames or slices with integer pixel values and associated metadata carried outside the coded pixel payload.

A color-space converter 804 performs deterministic conversion between color spaces when conversion is enabled. In one embodiment, the color-space converter 804 converts RGB to YUV using a declared matrix and declared rounding rules. In one embodiment, the color-space converter 804 converts YUV to RGB for output display using a declared matrix and declared rounding rules. In one embodiment, conversion is disabled and the codec encodes in the input color space. In one embodiment, the encoded stream indicates whether conversion was applied so that the decoder applies the corresponding inverse conversion when needed.

A luma plane buffer 806 stores luma data for YUV embodiments. A first chroma plane buffer 808 stores a first chroma plane. A second chroma plane buffer 810 stores a second chroma plane. In one embodiment, each plane buffer stores integer pixel values for the corresponding plane. In one embodiment, plane buffers store multiple frames for streaming or for look-ahead, provided that buffering rules remain deterministic for the selected mode.

A plane scaler 812 performs deterministic plane scaling when subsampling or resampling is enabled. In one embodiment, the plane scaler 812 performs chroma subsampling prior to decomposition, such as subsampling by a factor of two along one axis or both axes under a declared filter and rounding rule. In one embodiment, the plane scaler 812 performs inverse resampling at decode using the same declared filter and rounding rule. In one embodiment, plane scaling is disabled and all planes are processed at full resolution. In one embodiment, scaling configuration is indicated in the stream so that plane scaling and inverse scaling are applied consistently.

A tile buffer 814 partitions a plane into tiles and buffers tile pixel values. In one embodiment, tiles are rectangular regions of a fixed tile width and tile height. In one embodiment, tiles are non-overlapping. In another embodiment, tiles overlap under a declared rule, and overlap regions are handled deterministically at reconstruction. In one embodiment, tile formation includes deterministic padding rules at frame boundaries when frame dimensions are not an integer multiple of tile dimensions, such as padding with replicated edge pixels or padding with zeros under a declared rule.

A tile grid controller 816 defines tile indexing and tile traversal order. In one embodiment, the tile grid controller 816 defines a raster scan ordering over tiles. In another embodiment, the tile grid controller 816 defines a deterministic space-filling traversal such as a Morton order, provided that the traversal is declared and reproducible. In one embodiment, tile identifiers are implicit based on traversal order, and in another embodiment tile identifiers are carried in the stream for random access, provided that identifiers are interpreted deterministically.

A two-dimensional basis stage 818 provides a two-dimensional atom generation mechanism for tiles. In one embodiment, the two-dimensional basis stage 818 uses a separable basis in which a two-dimensional atom is formed as a product of a one-dimensional horizontal atom and a one-dimensional vertical atom. In another embodiment, the two-dimensional basis stage 818 uses a non-separable two-dimensional atom definition, provided that atoms remain addressable by deterministic identifiers and can be regenerated deterministically. In one embodiment, basis parameters are derived from the same normalized parameter derivation rules used for one-dimensional signals, mapped to per-axis grid parameters under a declared rule.

A tile decomposition engine 820 performs sparse decomposition of each tile. In one embodiment, the tile decomposition engine 820 uses matching pursuit or another deterministic sparse selection procedure to select a sparse set of atoms and coefficients that represent the tile and produces a residual tile. In one lossless embodiment, the tile decomposition engine 820 uses a declared spike budget and relies on exact residual coding to guarantee exact pixel reconstruction. In one near-lossless embodiment, the tile decomposition engine 820 terminates based on an objective distortion criterion and residual coding is performed under a declared reduced-precision rule. In one lossy embodiment, the tile decomposition engine 820 truncates spike selection and omits or reduces residual coding under a declared policy.

A tile coding stage 822 encodes tile spike lists and tile residuals. In one embodiment, the tile coding stage 822 encodes a spike count and encodes prime identifiers, center identifiers, and coefficients for each tile, and encodes residual information according to the selected mode. In one embodiment, the tile coding stage 822 encodes tiles in the traversal order defined by the tile grid controller 816. In one embodiment, the tile coding stage 822 includes per-tile integrity fields enabling detection of corruption.

A frame reconstruction stage 824 reconstructs tiles and assembles reconstructed planes and frames. In one embodiment, the frame reconstruction stage 824 decodes spike lists and residuals for each tile, regenerates referenced atoms, accumulates atoms weighted by coefficients to form a sparse tile component, maps the sparse component into an integer pixel domain under a declared mapping rule, adds the decoded integer residual in lossless mode, and outputs reconstructed tile pixels. The frame reconstruction stage 824 then places reconstructed tile pixels into a reconstructed plane according to the tile grid and padding rules and then forms reconstructed frames by combining reconstructed planes. When color-space conversion was applied at encode, the frame reconstruction stage 824 applies the corresponding inverse conversion under the declared rule for output.

A reconstructed frame output 826 provides reconstructed frames. In one embodiment, the reconstructed frame output 826 provides frames in the same color representation domain as the input. In another embodiment, the reconstructed frame output 826 provides frames in a specified output color space, provided that conversion is deterministic. In one embodiment, the reconstructed frame output 826 provides frames for display, storage, or subsequent processing. An output interface 828 outputs reconstructed frames. In one embodiment, the output interface 828 outputs frames to a file writer that stores reconstructed frames in a container. In one embodiment, the output interface 828 outputs frames to a display pipeline. In one embodiment, the output interface 828 outputs frames over a network transport. In one embodiment, the output interface 828 outputs frames along with integrity information enabling verification of reconstruction.

Concrete video and image configuration examples are supported as selectable profiles. In one embodiment, tiles are 8×8 pixels. In another embodiment, tiles are 16×16 pixels. In one embodiment, YUV 4:4:4 is processed with full-resolution luma and full-resolution chroma. In one embodiment, chroma planes are subsampled before decomposition under a declared rule and are reconstructed under the corresponding inverse rule. In one embodiment, integer pixel bit depths include 8-bit, 10-bit, and 12-bit representations, and bit depth is carried in configuration so that integer-domain residual coding and mapping rules preserve exact reconstruction in lossless mode.

High dynamic range handling is deterministic when enabled. In one embodiment, transfer function handling for HDR content is indicated as configuration, and pixel values are processed in a declared integer domain that corresponds to the coded representation. In one embodiment, if transfer function conversion is applied, conversion rules are declared and reversible when lossless output in the coded domain is required, and otherwise conversion is treated as a pre/post processing step outside the lossless guarantee for raw coded pixel integers.

Medical imaging embodiments are supported by treating each medical image slice as a frame and applying tile partitioning and lossless residual coding to ensure pixel-exact reconstruction. In one embodiment, metadata associated with medical images is carried separately from pixel payloads, and only pixel values are transformed by the codec. In one embodiment, reconstruction verification is supported by computing hashes of reconstructed pixel arrays and comparing to reference values carried outside the bitstream or computed independently.

A separable two-dimensional processing subsystem 900 is provided in which a two-dimensional atom is formed as a product of a one-dimensional atom along a first axis and a one-dimensional atom along a second axis, enabling efficient computation of projections and efficient regeneration of atoms for tile-based image and video coding. Separable processing supports deterministic computation by allowing intermediate results to be represented and accumulated under declared numeric-domain rules.

A horizontal atom generator 902 generates a one-dimensional atom along a horizontal axis of a tile. In one embodiment, the horizontal atom generator 902 generates discrete samples of a Gaussian-windowed oscillatory atom indexed by a prime identifier and centered at a horizontal center position. In one embodiment, the horizontal atom generator 902 uses a base parameter mapping rule to derive a per-axis base frequency and width for the tile width and uses a deterministic center-grid mapping rule to map a horizontal center identifier to an integer pixel coordinate within the tile. In one embodiment, the horizontal atom generator 902 supports discrete phase variants when phase variants are enabled, and the phase variant is selected by a discrete identifier.

A vertical atom generator 904 generates a one-dimensional atom along a vertical axis of a tile. In one embodiment, the vertical atom generator 904 generates discrete samples of a Gaussian-windowed oscillatory atom indexed by a prime identifier and centered at a vertical center position. In one embodiment, the vertical atom generator 904 uses a base parameter mapping rule to derive a per-axis base frequency and width for the tile height and uses a deterministic center-grid mapping rule to map a vertical center identifier to an integer pixel coordinate within the tile. In one embodiment, the vertical atom generator 904 supports discrete phase variants when phase variants are enabled, and the phase variant is selected by a discrete identifier.

A separable combiner 906 forms a two-dimensional atom as a product of the horizontal and vertical one-dimensional atoms. In one embodiment, for pixel coordinates (x, y) within a tile, the separable combiner 906 forms g(x,y)=g_h(x)*g_v(y), where g_h is a horizontal atom sample at x and g_v is a vertical atom sample at y. In one embodiment, g_h is indexed by a horizontal prime identifier and horizontal center identifier and g_v is indexed by a vertical prime identifier and vertical center identifier, and the combined two-dimensional atom is uniquely identified by the tuple of those identifiers and any enabled discrete variants.

A two-dimensional atom output 908 provides the combined atom for projection and reconstruction. In one embodiment, the two-dimensional atom output 908 provides an implicit representation in which the horizontal atom and vertical atom are provided separately and combined on-the-fly during projection. In another embodiment, the two-dimensional atom output 908 provides explicit two-dimensional values for a tile-sized support region by multiplying horizontal and vertical vectors.

A horizontal prime identifier 910 identifies the prime index used for the horizontal axis. A vertical prime identifier 912 identifies the prime index used for the vertical axis. In one embodiment, the horizontal and vertical prime identifiers are selected from the same prime set. In another embodiment, horizontal and vertical prime identifiers are selected from different bounded prime sets derived deterministically from per-axis mapping rules and per-axis constraints.

A tile origin identifier 914 identifies the origin or coordinate of a tile within a plane. In one embodiment, the tile origin identifier 914 is implicit based on tile traversal order and tile dimensions. In another embodiment, the tile origin identifier 914 is explicit and is carried in the stream for random access or error recovery. In one embodiment, the tile origin identifier 914 is used to determine global pixel coordinates of tile-local coordinates and to place reconstructed tile pixels into a reconstructed plane.

A luma tile buffer 916 stores a luma tile for processing. In one embodiment, the luma tile buffer 916 stores integer pixel values for a luma tile. In one embodiment, the luma tile buffer 916 stores values in an internal numeric domain used for projection, and in lossless mode integer-domain residuals are defined to guarantee exact reconstruction of luma values.

A chroma tile buffer 918 stores a chroma tile for processing. In one embodiment, the chroma tile buffer 918 stores integer pixel values for a chroma tile. In one embodiment, separate chroma tile buffers are used for separate chroma planes and are processed under the same separable mechanism, with per-plane configuration and per-plane residual coding rules.

A row processor 920 computes row-wise projections or intermediate values used in separable projection. In one embodiment, for a given horizontal atom g_h and a tile value array T(x, y), the row processor 920 computes intermediate values u(y)=sum_x T(x, y)*g_h(x) for each row index y, with summation computed in a declared numeric domain with declared rounding. In one embodiment, the row processor 920 computes u(y) values for multiple horizontal primes and centers in parallel, provided that operation ordering is deterministic under the declared domain.

A column processor 922 computes column-wise projections from the intermediate values to obtain coefficients for separable atoms. In one embodiment, for a given vertical atom g_v, the column processor 922 computes a coefficient a=sum_y u(y)*g_v(y), with summation computed in a declared numeric domain. In one embodiment, the column processor 922 computes coefficients for multiple vertical primes and centers in parallel, provided that reduction ordering and rounding are deterministic or that exact residual coding is used to guarantee lossless output.

A coefficient output 924 outputs coefficients for selected separable atoms. In one embodiment, the coefficient output 924 provides coefficients to a sparse selection engine that selects the best candidate according to a declared metric. In one embodiment, the coefficient output 924 provides coefficients in a declared coefficient domain suitable for coding.

A reconstructed tile output 926 outputs reconstructed tile values. In one embodiment, reconstructed tile output 926 is formed by accumulating selected separable atoms weighted by coefficients and then combining with a decoded residual under a declared reconstruction rule. In one lossless embodiment, the reconstructed tile output 926 is an integer tile whose pixel values match the original tile pixel values exactly.

Separable processing supports deterministic computational optimization by separating projection into two stages with explicit intermediate representations. In one embodiment, the intermediate values produced by the row processor 920 are stored in a declared fixed-point format so that subsequent column processing yields reproducible coefficients. In another embodiment, intermediate values are stored in higher precision and mapped under a declared rule prior to subsequent use. In one embodiment, separable processing reduces computational complexity relative to direct two-dimensional correlation evaluation by reusing one-dimensional computations across candidate combinations.

Separable processing supports multiple deployment approaches. In one embodiment, separable projection is implemented on a GPU by mapping rows to threads and using shared memory for horizontal atom samples. In one embodiment, separable projection is implemented on an FPGA using pipelined multiply-accumulate operations in the row processor 920 and column processor 922. In one embodiment, separable projection is implemented in software using vector instructions. In each case, deterministic ordering and rounding rules are preserved as required by the selected mode.

A hardware platform embodiment 1000 is provided in which the codec functions can be implemented using a combination of general-purpose processing, memory resources, and accelerator resources, including GPU, FPGA, and ASIC resources, while maintaining deterministic decoding behavior under the declared bitstream semantics and reconstruction rules. A host processor 1002 executes control flow for encoding and decoding, including stream parsing, configuration handling, buffer management, and orchestration of compute kernels or hardware blocks. In one embodiment, the host processor 1002 executes software that implements bitstream parsing and entropy coding and coordinates offloaded correlation computations. In one embodiment, the host processor 1002 executes software that performs both sparse decomposition and entropy coding in a CPU-only configuration.

A system memory 1004 stores working buffers used by encoding and decoding. In one embodiment, the system memory 1004 stores residual buffers, spike lists, coefficient buffers, intermediate projection results, tile buffers, and windowing buffers. In one embodiment, the system memory 1004 stores entropy coder state and model parameters for adaptive coding where used. In one embodiment, the system memory 1004 stores stream headers and configuration parameters and provides them to decoding modules.

A dictionary ROM 1006 stores atom-generation resources that enable deterministic atom regeneration. In one embodiment, the dictionary ROM 1006 stores parameter tables that include per-prime frequency parameters, normalization factors, and variant parameters. In one embodiment, the dictionary ROM 1006 stores lookup tables for Gaussian envelope values and cosine values indexed by deterministic indices. In one embodiment, the dictionary ROM 1006 stores waveform templates or compressed waveform resources that are expanded deterministically. In one embodiment, the dictionary ROM 1006 is replaced by a memory-mapped table in system memory, provided that the content and interpretation rules remain consistent.

A GPU accelerator 1008 provides parallel compute resources for correlation and reduction operations. In one embodiment, the GPU accelerator 1008 executes kernels that compute inner products between residuals and candidate atoms in parallel across primes and centers. In one embodiment, the GPU accelerator 1008 executes reduction kernels that select maxima and associated identifiers. In one embodiment, reduction behavior is controlled by deterministic tie-breaking rules implemented in the compare logic, and reduction ordering is fixed under the profile. In one embodiment, GPU acceleration is used for projection while entropy coding is executed on the host processor 1002.

An FPGA fabric 1010 provides programmable logic resources for implementing pipelined arithmetic and coding operations. In one embodiment, the FPGA fabric 1010 implements multiply-accumulate pipelines for inner products and implements comparator trees for argmax selection. In one embodiment, the FPGA fabric 1010 implements fixed-function entropy coding blocks for prime identifiers, center identifiers, coefficients, and residuals. In one embodiment, the FPGA fabric 1010 implements fixed-point atom generation and accumulation using lookup tables stored in dictionary ROM 1006 or block RAM.

An ASIC block 1012 provides fixed-function hardware resources for power-efficient operation. In one embodiment, the ASIC block 1012 implements a decode-only pipeline including spike list decoding, residual decoding, atom regeneration, accumulation, and assembly, and omits sparse decomposition. In one embodiment, the ASIC block 1012 implements both encoding and decoding for capture devices with constrained complexity. In one embodiment, the ASIC block 1012 supports a subset of profiles with bounded prime and center sets to reduce area and power, and streams encoded under those profiles are decoded deterministically.

A dot-product engine 1014 performs correlation computations. In one embodiment, the dot-product engine 1014 is implemented as a GPU kernel, an FPGA pipeline, or a CPU vector routine. In one embodiment, the dot-product engine 1014 supports on-the-fly atom generation and multiplies residual values by generated atom values to form partial sums. In one embodiment, the dot-product engine 1014 supports table-based atom evaluation by fetching precomputed atom values from dictionary resources.

A reduction engine 1016 performs reduction operations such as argmax selection and aggregation. In one embodiment, the reduction engine 1016 is implemented as a comparator tree that outputs a maximum correlation value and associated identifiers under deterministic tie-breaking. In one embodiment, the reduction engine 1016 performs deterministic accumulation reductions for coefficient computation and energy computation. In one embodiment, the reduction engine 1016 is configured so that operation ordering is fixed or otherwise declared, or lossless mode relies on exact residual coding to guarantee exact reconstruction.

A Golomb-Rice core 1018 performs Golomb-Rice coding and decoding for fields such as prime identifiers or other integer-valued fields. In one embodiment, the Golomb-Rice core 1018 encodes prime ranks using a parameter value fixed by profile. In one embodiment, the Golomb-Rice core 1018 encodes center deltas or other integer deltas where configured. In one embodiment, Golomb-Rice coding is used as a building block within a broader framing format. An arithmetic/range core 1020 performs arithmetic coding or range coding for fields such as coefficients and residual prediction errors where configured. In one embodiment, the arithmetic/range core 1020 implements a deterministic state update rule so that encoding and decoding remain synchronized. In one embodiment, the arithmetic/range core 1020 supports adaptive models with deterministic update rules. In one embodiment, the arithmetic/range core 1020 supports context selection based on decoded fields such as prime bands or center bands. A DSP slice array 1022 provides multiply-accumulate resources used for inner products, atom generation, and accumulation. In one embodiment, the DSP slice array 1022 is used in FPGA implementations to compute dot products and to implement pipelined accumulation. In one embodiment, the DSP slice array 1022 is used to evaluate envelope and oscillatory terms in fixed-point.

A control bus 1024 carries control and status signals among modules. In one embodiment, the control bus 1024 carries configuration registers that set mode policies, profile identifiers, and coding parameters. In one embodiment, the control bus 1024 carries status signals indicating buffer availability, error detection, and completion of compute kernels.

A storage interface 1026 provides access to persistent storage. In one embodiment, the storage interface 1026 reads and writes encoded bitstreams to files. In one embodiment, the storage interface 1026 reads and writes dictionary resources, profile definitions, or lookup tables.

A network interface 1028 provides access to network transport. In one embodiment, the network interface 1028 transmits encoded bitstreams for streaming or broadcast. In one embodiment, the network interface 1028 receives encoded bitstreams for decoding. In one embodiment, the network interface 1028 supports packetization and provides error detection metadata that can be used along with integrity fields carried in the bitstream.

Deterministic behavior is preserved across platform embodiments by constraining the interpretation of coded fields and by using declared numeric-domain rules for atom regeneration and accumulation. In one embodiment, fixed-point arithmetic is used for shared computations to ensure reproducibility. In another embodiment, exact residual coding in an integer output domain ensures bit-perfect output in lossless mode even when intermediate computations vary slightly across platform arithmetic implementations.

An alternative operational embodiment platform 1100 is provided in which the codec supports streaming operation, multi-channel handling, HDR handling, adaptive dictionary extensions, lossy operation modes, portable decode targets, medical imaging streams, telemetry streams, and network transport, with each operational mode controlled by declared and reproducible policies. A streaming path 1102 supports bounded-latency operation. In one embodiment, the streaming path 1102 encodes processing units as they become available and outputs records immediately or within a bounded buffering delay. In one embodiment, the streaming path 1102 uses a fixed processing unit size and a fixed maximum spike budget so that per-unit compute is bounded. In one embodiment, the streaming path 1102 includes restart points in the output stream at deterministic intervals to support resynchronization after packet loss.

A look-ahead buffer 1104 stores a bounded number of future processing units to support look-ahead decisions while maintaining bounded latency. In one embodiment, the look-ahead buffer 1104 stores one processing unit. In another embodiment, the look-ahead buffer 1104 stores zero processing units and the system operates in a strictly causal manner. In one embodiment, when look-ahead is used, any decision that depends on look-ahead is deterministic and based only on buffered values and declared rules.

A multi-channel input handler 1106 supports multi-channel signal processing. In one embodiment, the multi-channel input handler 1106 passes channels through unchanged and processes channels independently. In another embodiment, the multi-channel input handler 1106 applies a reversible channel transform that produces correlated representations such as difference channels, mid/side channels, or grouped differences, and the inverse transform is applied after decoding. In one embodiment, multi-channel configuration is declared so that a decoder applies the corresponding inverse transform deterministically.

A difference-channel generator 1108 produces difference channels for multi-channel embodiments. In one embodiment, the difference-channel generator 1108 computes integer differences between a reference channel and one or more other channels under a declared rule. In one embodiment, the difference-channel generator 1108 computes differences within declared groups of channels. In each case, the difference operation is reversible in the integer domain and supports exact reconstruction in lossless mode.

An HDR input handler 1110 supports high dynamic range processing. In one embodiment, the HDR input handler 1110 receives pixel values at higher bit depth such as 10-bit or 12-bit. In one embodiment, the HDR input handler 1110 preserves pixel values in a declared integer representation domain for lossless mode. In one embodiment, metadata indicating transfer function interpretation is carried as configuration and used deterministically for any required conversion.

An adaptive dictionary trainer 1112 supports adaptive dictionary extensions in which supplementary atoms are derived from content under a declared, reproducible procedure. In one embodiment, the adaptive dictionary trainer 1112 derives supplementary atoms from a fixed initial segment of content, such as an initial set of blocks or tiles, and the derivation procedure uses a fixed ordering rule and fixed quantization rules so that supplementary atoms are represented as deterministic parameters. In one embodiment, supplementary atoms are represented by parameter entries that can be transmitted in a header table or stored as part of a session profile.

A supplementary atom store 1114 stores supplementary atom parameters used for adaptive dictionary extensions. In one embodiment, the supplementary atom store 1114 stores per-atom parameters such as effective prime identifiers, center shapes, widths, phases, or other parameters used to regenerate the supplementary atoms deterministically. In one embodiment, supplementary atoms are bounded in count and parameter precision by declared limits. In one embodiment, the supplementary atom store 1114 is optional and is used only when an adaptive extension mode is enabled.

A lossy-mode selector 1116 selects lossy operation policies. In one embodiment, the lossy-mode selector 1116 selects a maximum spike count and a coefficient magnitude threshold. In one embodiment, the lossy-mode selector 1116 selects a residual policy that omits residual coding entirely. In another embodiment, the lossy-mode selector 1116 selects a residual policy that codes a reduced residual representation. In each case, the selected lossy policy is declared and deterministic.

A residual discard path 1118 omits residual coding when residual omission is selected. In one embodiment, the residual discard path 1118 causes the residual coder to omit residual payload fields and causes the decoder to treat the residual as a defined default residual such as zeros. In one embodiment, the residual discard path 1118 is enabled only when the mode indicator signals lossy operation and the policy indicates residual omission.

A portable decode device target 1120 represents low-power endpoints. In one embodiment, a portable decode device target 1120 includes a decode-only implementation that supports a subset of profiles with bounded prime and center sets. In one embodiment, the portable decode device target 1120 supports fixed-point atom regeneration and fixed-point accumulation to reduce power. In one embodiment, the portable decode device target 1120 supports streaming decode with bounded buffering.

A medical imaging input handler 1122 supports medical imaging streams. In one embodiment, the medical imaging input handler 1122 partitions medical images into tiles and processes tiles under lossless mode to maintain pixel-exact reconstruction. In one embodiment, medical imaging metadata is preserved outside the coded pixel payload and is not modified by the codec. In one embodiment, integrity verification is performed by hashing reconstructed pixel data.

A telemetry input handler 1124 supports telemetry streams. In one embodiment, telemetry values are treated as one-dimensional samples and partitioned into blocks. In one embodiment, the telemetry input handler 1124 inserts synchronization markers at deterministic intervals. In one embodiment, telemetry blocks include integrity fields to detect corruption.

A transmitter node 1126 supports network transmission of encoded data. In one embodiment, the transmitter node 1126 packetizes encoded processing-unit records. In one embodiment, the transmitter node 1126 includes forward error correction outside the core codec payload. In one embodiment, packetization preserves record boundaries or includes record identifiers to enable deterministic reassembly.

A receiver node 1128 supports network reception and decode. In one embodiment, the receiver node 1128 reassembles records and validates integrity fields. In one embodiment, the receiver node 1128 discards corrupted records and resynchronizes at restart points. In one embodiment, the receiver node 1128 provides decoded output to a playback or display pipeline.

A deployment controller 1130 coordinates operational configuration. In one embodiment, the deployment controller 1130 selects profiles and mode policies based on declared constraints such as target bitrate, compute budget, and required reconstruction mode. In one embodiment, the deployment controller 1130 configures buffer sizes, look-ahead, and restart point intervals for streaming operation. In one embodiment, the deployment controller 1130 logs configuration parameters and integrity results for auditing and verification.

Operational determinism is maintained in each of the alternative embodiments by ensuring that any adaptive behavior is governed by declared rules and that any additional data required for decoding, such as supplementary atom parameters or mode parameters, is carried in the stream or implied by a declared profile in an unambiguous manner.

An application environment 1200 is provided in which the codec is deployed in archival systems, studio workflows, medical imaging archives, cloud transcoding services, live broadcast pipelines, and telemetry transmission systems, with each environment benefiting from deterministic decode behavior and selectable lossless, near-lossless, and lossy operation. An archival music server 1202 stores encoded audio content and serves it for retrieval and streaming. In one embodiment, the archival music server 1202 encodes master audio content using lossless mode so that reconstructed output samples match original samples exactly. In one embodiment, the archival music server 1202 stores encoded bitstreams along with integrity metadata such as hashes computed over original and reconstructed content. In one embodiment, the archival music server 1202 supports partial retrieval by enabling random access to processing-unit records when record boundaries and indexing are available.

A studio workstation 1204 supports professional audio production workflows. In one embodiment, the studio workstation 1204 encodes and decodes high-resolution audio masters using lossless mode to preserve exact sample values. In one embodiment, the studio workstation 1204 encodes multi-channel session content, including correlated channel representations, and decodes it deterministically for playback and editing. In one embodiment, the studio workstation 1204 supports near-lossless mode for temporary working files under an objective distortion criterion while preserving a deterministic decode output for reproducible mixing and editing. A PACS archive 1206 stores medical imaging data. In one embodiment, the PACS archive 1206 stores encoded pixel payloads for images and slices under lossless mode so that reconstructed pixel values match original pixel values exactly. In one embodiment, the PACS archive 1206 stores medical metadata separately from the coded pixel payload and preserves it unchanged. In one embodiment, the PACS archive 1206 supports verification of reconstruction by storing or computing integrity hashes of pixel arrays after decode.

A cloud transcoding service 1208 accepts input media and outputs encoded results. In one embodiment, the cloud transcoding service 1208 receives input files through an upload interface 1210 and encodes content using a selected profile and mode policy. In one embodiment, the cloud transcoding service 1208 outputs encoded bitstreams and stores them in a compressed output store 1214. In one embodiment, the cloud transcoding service 1208 supports lossless mode for archival and professional workflows and near-lossless or lossy modes for bandwidth-limited delivery workflows.

An upload interface 1210 receives content for encoding in a cloud environment. In one embodiment, the upload interface 1210 supports chunked upload and deterministic reassembly of input content prior to encoding. In one embodiment, the upload interface 1210 validates content format and extracts configuration parameters such as sample rate, frame size, and bit depth needed to select a codec profile.

A verification hash generator 1212 produces integrity metadata. In one embodiment, the verification hash generator 1212 computes hashes of original input content and hashes of decoded output content for lossless mode verification. In one embodiment, the verification hash generator 1212 computes per-record checksums or per-block hashes to support localized integrity checking. In one embodiment, the verification hash generator 1212 stores integrity metadata alongside encoded content in the compressed output store 1214.

A compressed output store 1214 stores encoded outputs and associated metadata. In one embodiment, the compressed output store 1214 stores encoded bitstreams, configuration information, indexing information for random access, and integrity metadata. In one embodiment, the compressed output store 1214 supports versioning so that encoded outputs can be associated with specific codec profiles and decoding configurations.

A satellite platform 1216 generates telemetry data for transmission. In one embodiment, telemetry streams are segmented into blocks and encoded using lossless mode when exact reconstruction is required, or encoded using near-lossless or lossy modes under objective policies when link constraints require further bitrate reduction. In one embodiment, telemetry encoding includes periodic synchronization markers and integrity fields to support robust decoding. A downlink channel 1218 transports encoded telemetry. In one embodiment, the downlink channel 1218 is bandwidth constrained and packetized, and encoded records are transmitted as packets. In one embodiment, record integrity fields support detection of corruption and deterministic handling of lost data.

A ground station 1220 receives and decodes telemetry. In one embodiment, the ground station 1220 reassembles encoded telemetry records, validates integrity fields, decodes spike lists and residual payloads, and reconstructs telemetry values deterministically. In one embodiment, the ground station 1220 performs resynchronization at markers after packet loss.

A live broadcast encoder 1222 supports real-time encoding of audio and video. In one embodiment, the live broadcast encoder 1222 uses streaming operation with bounded buffering and a bounded spike selection budget per processing unit. In one embodiment, the live broadcast encoder 1222 selects near-lossless or lossy mode under objective truncation and residual policies to meet real-time bitrate constraints. In one embodiment, record boundaries are aligned to transport packets to support deterministic decode behavior under packetization.

A live broadcast receiver 1224 receives and decodes broadcast content. In one embodiment, the live broadcast receiver 1224 decodes records in real time, validates integrity metadata, resynchronizes at restart points when needed, and reconstructs output deterministically according to the selected mode. In one embodiment, the live broadcast receiver 1224 outputs reconstructed audio and video to playback pipelines.

An endpoint playback or diagnostic station 1226 outputs decoded content and can verify reconstruction. In one embodiment, the endpoint playback or diagnostic station 1226 compares decoded output to reference integrity metadata when available. In one embodiment, the endpoint playback or diagnostic station 1226 provides diagnostic outputs such as decoded spike statistics or residual statistics for monitoring, provided that such diagnostics do not alter decoded output.

Each deployment environment described herein can select a mode policy and profile that satisfies its operational constraints, including exact reconstruction for archival and medical use, bounded objective distortion for near-lossless use, and deterministic truncation policies for lossy use, while relying on deterministic decoding semantics and consistent regeneration of prime-indexed Gaussian-spike atoms and residual combination rules.

Alternative implementations are supported in which modules can be combined, split, reordered, pipelined, parallelized, or distributed across compute resources, provided that the encoded payload retains unambiguous semantics for prime identifiers, center identifiers, coefficients, residual interpretation, and record boundaries so that a decoder can reconstruct output deterministically for the selected mode.

Equivalent signal representations are supported in which an input signal is represented as signed integers, unsigned integers with offsets, fixed-point values, or other discrete representations, provided that the representation used for defining lossless equality is declared for the stream and residual coding preserves exact equality in that declared domain for lossless mode.

Equivalent processing-unit representations are supported in which processing units correspond to non-overlapped blocks, overlapped blocks, tiles, overlapping tiles, or grouped tiles, provided that the partitioning and assembly rules are deterministic and the encoded payload conveys any information required for the decoder to reproduce the same partitioning and assembly.

Equivalent prime identifier representations are supported in which a prime identifier is the prime value itself, a rank within an ordered list of primes, or another identifier that deterministically resolves to a prime value under a declared rule, provided that the mapping from identifier to prime value is unambiguous for decoding.

Equivalent center identifier representations are supported in which a center identifier is an integer index into a grid, an encoded coordinate, or another identifier that deterministically resolves to an integer center position under a declared rule, provided that the mapping from identifier to center position is unambiguous for decoding and consistent with the atom generation rules.

Equivalent coefficient representations are supported in which coefficients are represented as signed fixed-point integers with declared scaling, sign-magnitude values, two's-complement values, or other discrete coefficient encodings, provided that the decoder can reconstruct the same coefficient values in the declared coefficient domain and apply them to atom regeneration consistently.

Equivalent residual representations are supported in which residuals are coded directly as integers, coded as integer prediction errors under a declared predictor, coded under reduced precision for near-lossless mode under a declared quantization rule, or omitted under a declared lossy policy, provided that the residual policy is unambiguous for decoding and produces the intended reconstruction behavior for the selected mode.

Equivalent predictor embodiments are supported in which residual prediction uses fixed predictors, adaptive predictors with deterministic update rules, spatial predictors for two-dimensional content, temporal predictors across frames when enabled, or hybrid predictors, provided that any state update and boundary handling are deterministic and depend only on already decoded information.

Equivalent entropy coding embodiments are supported in which primes, centers, coefficients, and residual values are coded using Rice-family codes, arithmetic coding, range coding, Huffman coding, or other entropy coding techniques, provided that the coding scheme and any model update rules are deterministic and decodable without ambiguity.

Equivalent dictionary generation embodiments are supported in which atoms are generated procedurally, generated using parameter tables, generated using waveform templates, generated using a mixture of procedural generation and table lookup, or generated using supplementary learned atoms transmitted as parameters, provided that the decoder can regenerate the same atom values required for reconstruction in the declared numeric domain rules or can rely on exact residual coding in lossless mode to guarantee output equality.

Equivalent numeric-domain embodiments are supported in which atom generation and projection computations use fixed-point arithmetic with declared scaling and rounding, floating-point arithmetic with declared precision and declared operation ordering, or mixed arithmetic, provided that the reconstruction semantics for lossless mode are satisfied either by matching computations sufficiently or by defining and coding a residual exactly in the declared output domain.

Boundary handling is deterministic in embodiments that apply windows, overlap-add, padding, subsampling, resampling, or color conversion. In one embodiment, overlap-add uses deterministic window coefficients and deterministic normalization. In one embodiment, padding uses deterministic edge replication or deterministic constant padding. In one embodiment, subsampling and resampling use deterministic filters and deterministic rounding. In one embodiment, color conversion uses deterministic matrices and deterministic rounding.

Record integrity handling is supported in embodiments that include integrity fields such as checksums or hashes. In one embodiment, integrity fields are verified prior to committing reconstructed output for a record. In one embodiment, corrupted records are discarded or flagged under a deterministic rule, and resynchronization is performed at restart points when present. In one embodiment, record indexing supports random access and partial decode without requiring decoding of all prior records, provided that any required state is either reset at index points or carried explicitly.

Versioning and compatibility are supported by associating encoded content with identifiers that determine decoding semantics. In one embodiment, a version identifier and a profile identifier select the interpretation of constants, mapping rules, dictionary bounds, coding rules, and mode semantics. In one embodiment, unsupported versions or unsupported profiles are rejected rather than decoded with undefined behavior.

Optional monitoring outputs can be generated without altering decoded outputs. In one embodiment, statistics such as spike counts, prime distributions, coefficient magnitude distributions, and residual energy ratios are computed for monitoring or diagnostics. In one embodiment, such statistics are stored externally or transmitted as side information separate from the coded payload and are not required for reconstruction.

The term “comprising” is used in an open-ended sense so that additional elements or steps may be present. The term “including” is used in an open-ended sense. The term “based on” means based at least in part on. As used herein, “Recognition Science (RS)” refers to the Recognition Physics framework as described in the accompanying Recognition-Science-Full-Theory.txt, and any RS-consistency statements describe certain embodiments and do not require that every embodiment be derived from RS. The term “configured to” denotes capability. The term “or” is inclusive unless the context indicates otherwise. The disclosed embodiments are illustrative examples, and technically compatible combinations and subcombinations of disclosed features are supported, and references herein to Recognition Science are provided as an illustrative theoretical context for certain embodiments and do not limit the scope of the claims, and nothing herein, including any discussion in the Background, is an admission that any feature, aspect, or implementation detail is required, conventional, or known in the prior art.

A worked example for a one-dimensional audio block illustrates formation of a spike list and an exact residual in a lossless operating mode. In one embodiment, an input audio block is expressed as a vector of integer samples in a declared integer domain, the sparse component is computed in an internal numeric domain by selecting atoms and coefficients, the sparse component is mapped into the integer domain using a declared mapping rule, and an integer residual is formed as the exact integer difference between the original integer block and the mapped sparse component. In that embodiment, the integer residual is entropy coded exactly, and the decoder regenerates the same atoms, accumulates the same coefficient-weighted sparse component, applies the same mapping rule to obtain the integer-domain sparse component, and adds the decoded integer residual to reproduce the original integer samples exactly.

A worked example for a two-dimensional luma tile illustrates separable projection and reconstruction with an exact residual in a lossless operating mode. In one embodiment, a tile of integer luma values is processed by selecting separable atoms formed from horizontal and vertical one-dimensional atoms, coefficients are computed from separable projections in a declared numeric domain, and a sparse tile component is accumulated. The sparse tile component is mapped into the integer pixel domain using a declared mapping rule and an integer residual tile is formed as the exact integer difference between the original integer tile and the mapped sparse tile component. The integer residual tile is entropy coded exactly, and the decoder regenerates the same separable atoms, accumulates the sparse tile component, applies the same mapping rule, and adds the decoded integer residual tile to reproduce the original integer pixels exactly.

A near-lossless operation example illustrates termination by an objective residual criterion. In one embodiment, sparse selection continues until a residual-energy ratio bound is satisfied under a declared energy computation rule, and residual coding is performed under a declared reduced-precision rule such that reconstructed output satisfies the bound. In one embodiment, the reduced-precision residual rule is a deterministic quantization step size applied to residual values, and the decoder applies the corresponding inverse interpretation so that the reconstruction behavior is reproducible for the same input and same declared configuration. A lossy operation example illustrates deterministic truncation by a spike budget and a residual policy. In one embodiment, sparse selection is limited to a declared maximum spike count and coefficients below a declared magnitude threshold are not recorded, and residual coding is omitted so that reconstructed output equals the sparse component alone. In another embodiment, sparse selection is limited to a declared maximum spike count and a reduced residual representation is coded, such as a lower-precision residual, and the decoder applies the same reduced residual interpretation. In each case, the truncation and residual policy are deterministic and produce reproducible output for the same input and same configuration.

An example of deterministic selection tie behavior illustrates reproducibility when candidates compare equal under the compare rule. In one embodiment, if two candidate atoms produce equal objective metric values, a deterministic ordering of candidate identifiers determines which candidate is selected, and the selection does not depend on implementation-specific iteration order. In one embodiment, the deterministic ordering is based on prime identifiers and center identifiers and optional variant identifiers when enabled. In one embodiment, the compare rule is defined in a fixed-point domain so that equality comparisons are exact, and in another embodiment the compare rule uses a declared tolerance and treats values within tolerance as equal for selection purposes.

An example of streaming operation illustrates bounded buffering and resynchronization. In one embodiment, processing-unit records are emitted as soon as processing units are formed, and a bounded look-ahead policy limits buffering delay. In one embodiment, restart points are inserted at deterministic intervals, and each restart point provides a record boundary at which decoding state is reset or fully specified so that decoding can resume after loss without reliance on missing prior state. In one embodiment, corrupted records are detected using integrity fields and are discarded under a deterministic policy, and output for discarded records is handled under a deterministic concealment or omission policy when concealment is enabled.

An example of multi-channel operation illustrates reversible channel transforms for redundancy reduction. In one embodiment, a reference channel is encoded directly and one or more difference channels are formed as integer differences relative to the reference, and sparse decomposition and residual coding operate on the reference and difference channels. In one embodiment, the inverse transform reconstructs original channels exactly in lossless mode because differences are integer-exact and residual coding completes exact reconstruction of each transformed channel.

An example of medical imaging operation illustrates pixel-exact reconstruction and integrity verification. In one embodiment, medical image slices are partitioned into tiles and each tile is encoded in lossless mode using exact integer residual coding so that reconstructed pixel values match original pixel values exactly. In one embodiment, integrity hashes of reconstructed pixel arrays are computed and compared to reference values stored alongside the encoded payload, providing a deterministic verification step.

An example of telemetry operation illustrates deterministic blocking and error handling under packetized transport. In one embodiment, telemetry samples are grouped into fixed-size blocks and encoded, and record identifiers or markers support deterministic alignment of decoded samples to time indices. In one embodiment, packet loss results in loss of specific processing-unit records, and the receiver resynchronizes at the next marker and resumes decoding without misalignment. In one embodiment, missing records are flagged and downstream consumers are informed deterministically that corresponding samples are unavailable.

A set of deterministic boundary rules supports correct handling of partial blocks and partial tiles. In one embodiment, audio streams whose length is not an integer multiple of hop size are padded or truncated under a declared rule, and padding values are deterministic. In one embodiment, images whose dimensions are not an integer multiple of tile size are padded under a declared rule, and padding is removed deterministically after reconstruction. In one embodiment, when windowing is used for overlapped audio blocks, the analysis and synthesis windows and normalization are deterministic and are applied consistently so that overlap-add produces stable results in all supported configurations.

A deterministic configuration validation procedure supports robust decode behavior. In one embodiment, a decoder validates that signaled configuration values are within supported ranges and that required payload fields are present for the selected mode. In one embodiment, unsupported configurations are rejected. In one embodiment, configuration validation ensures that reconstruction behavior is defined and reproducible for all accepted streams.

A file container embodiment supports storage of the compressed payload along with configuration metadata in a manner that enables deterministic interpretation of the stream. In one embodiment, the container stores a stream header including configuration parameters such as sampling rate, channel count, bit depth, frame dimensions, tile dimensions, and color representation, and the container stores the compressed payload as a sequence of records corresponding to processing units. In one embodiment, the container stores an index mapping from time offsets, sample offsets, or frame numbers to record boundaries so that random access decoding can begin at a selected record boundary.

A random-access embodiment supports decoding from a non-initial record boundary while preserving defined decoding behavior. In one embodiment, records are independently decodable because required configuration is present at the stream header and any adaptive coding state is either fixed or reset at declared points. In one embodiment, restart points are inserted at deterministic intervals and each restart point provides a boundary at which predictor state and arithmetic coder state are reset to declared initial values, enabling decoding to begin at or after the restart point without dependence on earlier records.

An indexing embodiment supports efficient seeking and partial decode. In one embodiment, an index table stores byte offsets to record boundaries and stores record identifiers such as block numbers or tile identifiers. In one embodiment, the index table stores per-record lengths for the spike list payload and residual payload so that a decoder can skip records without parsing internal fields. In one embodiment, the index table stores a mapping between tile identifiers and spatial locations within frames to enable partial frame reconstruction by decoding only a subset of tiles.

A packetization embodiment supports transport of records over networks where packet loss or corruption can occur. In one embodiment, each record is packetized as one or more packets, and packets carry record identifiers and offsets so that records can be reassembled deterministically. In one embodiment, record boundaries are aligned to packet boundaries when possible to reduce reassembly complexity. In one embodiment, integrity fields at the record level enable detection of corruption independent of network checksums.

A concealment embodiment defines deterministic handling when records are missing or corrupted. In one embodiment, missing records are treated as absent and the output includes gaps or flags indicating absence. In another embodiment, a concealment policy is applied in which missing audio blocks are replaced by a deterministic fill such as zeros or a deterministic extrapolation based on the most recent decoded samples, and the concealment policy is declared and reproducible. In one embodiment for video, missing tiles are replaced by deterministic fills such as copying the corresponding tile from a previous decoded frame when available, or filling with a constant value, under a declared rule.

A concurrency embodiment supports parallel encoding and decoding while preserving deterministic outputs. In one embodiment, processing units are processed in parallel across cores or compute units, and results are committed to the output bitstream in a deterministic record order. In one embodiment, spike selection within each processing unit uses deterministic candidate enumeration and deterministic tie-breaking so that parallel evaluation does not change selection results. In one embodiment, entropy coding uses deterministic coder state initialization per record or per restart interval to avoid dependence on nondeterministic scheduling.

A memory management embodiment supports bounded memory operation for streaming and embedded deployments. In one embodiment, buffers for spike lists, residuals, and intermediate projections are allocated to a fixed maximum size derived from declared maximum spike count, declared maximum block size or tile size, and declared maximum number of concurrent processing units. In one embodiment, when a processing unit produces fewer spikes than the maximum, unused buffer capacity is ignored without affecting decoding semantics. In one embodiment, memory usage is bounded so that a portable decode endpoint can operate without dynamic allocation.

A fixed-point implementation embodiment supports exactness and reproducibility by using declared scaling and saturation. In one embodiment, atom generation uses fixed-point lookup tables for Gaussian envelopes and cosine values, and table values are represented with a declared bit width and scaling. In one embodiment, multiplication and accumulation use declared rounding and saturation. In one embodiment, coefficient values are represented as fixed-point integers with declared scaling and are decoded and applied identically across implementations. A floating-point implementation embodiment supports efficient computation while preserving lossless output via exact residual coding. In one embodiment, correlation and coefficient extraction are performed in floating-point, and a sparse estimate is formed and then mapped to the integer output domain under a declared rule. The residual is defined as the integer-domain difference between original integers and the mapped sparse estimate and is coded exactly, so reconstructed integers match original integers in lossless mode despite any intermediate floating-point variation.

An arithmetic coder state embodiment supports deterministic coding and decoding when arithmetic coding or range coding is used. In one embodiment, coder state is initialized to a declared initial state at the start of the stream or at restart points. In one embodiment, any adaptive model updates depend only on previously coded symbols and use declared update rules. In one embodiment, contexts used for adaptive coding are derived only from decoded identifiers and decoded prior symbols so that encoder and decoder remain synchronized.

A security and robustness embodiment supports rejecting malformed or adversarial payloads. In one embodiment, bounds checks ensure that decoded spike counts do not exceed declared limits. In one embodiment, identifier validation ensures that prime identifiers and center identifiers are within permitted ranges for the current configuration. In one embodiment, length validation ensures that payload lengths are consistent with available data. In one embodiment, a decoder rejects records that violate declared bounds rather than allocating excessive memory or producing undefined behavior.

A verification embodiment supports test vectors and regression checks. In one embodiment, a set of reference input blocks, reference encoded payloads, and reference decoded outputs are maintained and used to verify that an implementation produces expected outputs. In one embodiment, verification includes lossless checks that reconstructed integer outputs match original integer inputs exactly. In one embodiment, verification includes near-lossless checks that reconstructed output satisfies declared distortion criteria under the declared evaluation rule. In one embodiment, verification includes checks that parsing, bounds validation, and integrity validation behave deterministically for malformed inputs.

A manufacturing and deployment embodiment supports hardware verification. In one embodiment, a decode-only hardware implementation is verified by decoding reference payloads and comparing reconstructed outputs to reference outputs. In one embodiment, a hardware implementation includes a built-in self-test mode that decodes a stored reference payload from memory and reports a pass/fail status based on an exact match. In one embodiment, hardware and software implementations share the same profile identifiers and interpret payload fields consistently.

A cloud-scale embodiment supports reproducible outputs across distributed instances. In one embodiment, encoding jobs specify explicit profile identifiers and configuration parameters so that outputs are reproducible. In one embodiment, instance-to-instance variability in floating-point operations is tolerated in lossless mode by defining and coding integer-domain residuals exactly. In one embodiment, near-lossless and lossy modes define objective criteria and truncation policies so that outputs remain reproducible for a given input and profile.

A device-scale embodiment supports low-power decoding. In one embodiment, a portable endpoint decodes spike list entries and regenerates atoms using fixed-point tables and accumulates contributions using bounded precision, and exact residual decoding yields bit-perfect integer outputs in lossless mode. In one embodiment, a subset of profiles with bounded prime and center sets is used to reduce compute and memory.

A dataset-scale embodiment supports batch encoding of large collections. In one embodiment, batch jobs encode audio archives or image archives by selecting profiles that preserve exact reconstruction for archival content. In one embodiment, indexing and integrity metadata enable later validation that decoded outputs match original inputs. In one embodiment, batch encoding logs record profile identifiers and configuration values used for each encoded asset.

The disclosed systems and methods support technically compatible combinations and subcombinations of the described behaviors, including combinations of profile selection, record indexing, restart points, packetization, integrity verification, fixed-point or floating-point internal computation, and exact or reduced residual policies as determined by the selected operating mode.

In one embodiment, each processing-unit record begins with a compact record header that is sufficient to enable a decoder to determine the operating mode for the record, to determine whether a residual payload is present, and to determine how many spike entries are present, without requiring the decoder to parse arbitrary prior records. In one embodiment, the record header includes a mode indicator and a spike count, and the record header includes a residual-present indicator that is implied by the mode indicator for lossless mode and is explicitly indicated for other modes when residual policy can vary.

In one embodiment, the spike count is encoded using a self-delimiting integer code such that the decoder can decode the spike count without needing an external length field. In one embodiment, the spike count code is selected so that small spike counts require fewer bits, and the mapping from the codeword to the spike count is fixed by the profile. In one embodiment, the spike count is constrained by a declared maximum spike count, and the decoder validates that the decoded spike count does not exceed the maximum spike count before allocating or consuming spike entry fields.

In one embodiment, the spike list payload is encoded as a sequence of spike entries, and each spike entry includes a prime identifier field, a center identifier field, and a coefficient field, and optionally includes a variant field when variants are enabled. In one embodiment, the prime identifier field and the center identifier field are encoded as integers in declared ranges, and the coefficient field is encoded as a signed integer in a declared coefficient domain. In one embodiment, the coefficient field includes a sign bit and a magnitude code, and the magnitude code is entropy-coded using a declared model that is updated deterministically from previously decoded magnitudes.

In one embodiment, spike entries are encoded in an interleaved representation in which each spike entry's prime identifier, center identifier, optional variant identifier, and coefficient are encoded consecutively, and the decoder reconstructs spike entries as it decodes them. In another embodiment, spike entries are encoded in a de-interleaved representation in which all prime identifiers for the record are encoded first, then all center identifiers, then all coefficients, and the decoder reconstructs spike entries by combining sequences in the declared order; in that embodiment, the decoder validates that each sequence has the correct length equal to the spike count.

In one embodiment, the record includes explicit length fields for the spike list payload and residual payload so that a decoder can skip forward without decoding the content and can validate that payload lengths are consistent with available data. In another embodiment, length fields are omitted and the record boundary is determined by decoding exactly the declared number of spike entries and then decoding a residual payload whose length is determined by processing-unit size and residual coding configuration; in that embodiment, the decoder validates that residual payload decoding consumes exactly the expected number of symbols and does not underflow or overflow the record.

In one embodiment, when a restart point is used, the restart point coincides with a record boundary and includes a restart marker that can be searched for in a byte stream. In one embodiment, a restart point also resets any adaptive entropy-coding model state to a declared initial state, resets any predictor state for residual decoding to a declared initial state, and resets any context state derived from prior records. In one embodiment, a decoder that begins decoding at a restart point can decode subsequent records without needing to decode records prior to the restart point.

In one embodiment, adaptive coding is permitted only when the update rule depends solely on previously decoded symbols and previously decoded identifiers within the same stream, and the update rule is deterministic and bounded. In one embodiment, model parameters are updated by fixed formulas using integer arithmetic or fixed-point arithmetic so that the same updates occur at encoder and decoder. In one embodiment, adaptation is constrained to reset at restart points or at declared intervals so that long-term drift cannot accumulate and random access can be supported.

In one embodiment, a deterministic mapping rule is used to convert an internal sparse component estimate into an integer reconstruction domain for lossless mode. In one embodiment, the mapping rule is an elementwise rounding rule that rounds toward zero. In another embodiment, the mapping rule is an elementwise rounding rule that rounds to nearest with ties resolved toward even, and the tie-resolution rule is fixed by profile. In one embodiment, the mapping rule includes an elementwise saturation rule that clamps values to the representable range of the output bit depth, and the saturation bounds are determined from bit depth and signedness under a declared rule.

In one embodiment, the integer-domain residual for lossless mode is defined after applying the mapping and saturation rules so that reconstruction is exact even in the presence of clipping. In one embodiment, for an original integer processing unit x and an internal sparse estimate s, the mapped estimate m is defined as m=clamp(round(s)), and the residual r is defined as r=x−m in an integer domain wide enough to represent the difference without overflow, and r is encoded exactly. In that embodiment, the decoder reconstructs m using the same clamp and round rules and reconstructs x as x=m+r with an integer addition performed in a declared width and then mapped back into the output range under a declared rule.

In one embodiment, coefficient application is defined in a declared coefficient domain so that multiplication and accumulation are reproducible. In one embodiment, coefficients are represented as fixed-point integers with a declared scale factor, atoms are represented as fixed-point values with a declared scale factor, and the product uses a declared intermediate width and a declared rounding rule before accumulation. In one embodiment, accumulation uses a declared accumulator width sufficient to avoid overflow for the maximum spike count and maximum coefficient magnitude, and if saturation is used in accumulation it is declared and consistent across implementations.

In one embodiment, overlap-add reconstruction in audio is defined with deterministic rounding and normalization at each step to preserve exactness in lossless mode. In one embodiment, overlap-add is implemented in an internal higher-precision domain and the final output sample is mapped to the integer output domain using the same mapping and saturation rules described above. In one embodiment, when windowing is enabled, window coefficients are represented in a fixed-point domain with declared scaling, and multiplication by window coefficients uses declared rounding and accumulator widths so that overlap-add results are reproducible.

In one embodiment, tile assembly in image and video is defined with deterministic padding removal and deterministic placement. In one embodiment, when padding is used at frame boundaries, the decoder reconstructs padded tiles and then removes padding under a declared rule to produce the original frame dimensions. In one embodiment, when subsampling and resampling are enabled, the resampling filter coefficients are declared and represented in a deterministic fixed-point form, and boundary handling for resampling is declared so that reconstructed planes are reproducible.

In one embodiment, silence blocks in audio are handled deterministically by permitting a spike count of zero and encoding a residual that reconstructs the original block exactly. In one embodiment, the encoder detects a silence block under a declared rule, such as all samples equal to zero or all samples equal to a constant value, and the encoder sets spike count to zero and encodes the block using residual coding, and the decoder reconstructs exactly using the residual. In one embodiment, constant tiles in image/video are handled similarly by permitting spike count zero and coding a residual that reconstructs the constant values exactly, optionally with a predictor that compresses constant values efficiently.

In one embodiment, a short final block or partial block at the end of an audio stream is handled deterministically by applying a declared padding rule or a declared truncation rule. In one embodiment, padding uses deterministic values, such as zeros or edge replication, and the decoder removes the padded samples after reconstruction under a declared rule. In one embodiment, truncation encodes only the remaining samples and indicates the valid sample count in a record field so that the decoder outputs only the valid sample count.

In one embodiment, when a record is corrupted and integrity metadata indicates failure, the decoder handles the record under a deterministic policy. In one embodiment, the decoder discards the record and outputs a flagged gap. In one embodiment, the decoder outputs a deterministic concealment, such as zeros for an audio block or a constant-value tile for a video tile, and the concealment policy is fixed by configuration. In one embodiment, when restart points are present, the decoder discards corrupted records until the next restart point and resumes decoding from the next restart point.

In one embodiment, decoding includes explicit bounds checks that prevent resource exhaustion. In one embodiment, the decoder validates that spike count does not exceed a declared maximum. In one embodiment, the decoder validates that prime identifiers and center identifiers are within declared ranges. In one embodiment, the decoder validates that any length fields are consistent with remaining buffer length. In one embodiment, the decoder validates that coefficients decode to values within declared bounds. In one embodiment, the decoder rejects records that violate bounds rather than attempting to decode undefined payloads.

In one embodiment, profiles are defined so that common configurations are supported as stable operating points. In one embodiment, a profile fixes a block size, a hop size, a stride, a prime bound rule, coefficient representation rules, residual predictor rules, and restart point rules. In one embodiment, a profile fixes a tile size, plane handling rules, subsampling rules, per-axis parameter mapping rules, and residual predictor rules. In one embodiment, a profile defines whether adaptive coding is enabled and whether adaptive dictionary extensions are enabled, and if enabled defines how they are represented and reset.

In one embodiment, distributed encoding and decoding are supported by ensuring that record semantics are self-contained and that restart points provide state reset. In one embodiment, a large input is partitioned into segments at restart point boundaries, segments are encoded independently on separate compute nodes, and encoded segments are concatenated to form a complete stream because restart points reset coder state to declared initial state. In one embodiment, distributed decoding similarly decodes segments independently starting at restart points.

In one embodiment, a deterministic audit log can be produced that records per-record spike counts, prime distributions, coefficient statistics, and residual sizes without affecting reconstruction. In one embodiment, audit outputs are computed from already decoded fields and are stored externally, and reconstruction is not conditioned on audit outputs.

In one embodiment, prime identifier ranges and center identifier ranges are declared as part of configuration so that a decoder can validate identifier values before attempting atom regeneration. In one embodiment, a prime identifier resolves to a prime number p that is bounded by a maximum prime bound derived from configuration and mapping rules, and if a decoded prime identifier would resolve to a prime number exceeding the bound, the decoder treats the record as invalid. In one embodiment, a center identifier resolves to an integer center position within a processing unit, and if a decoded center identifier would map outside the permissible index range, the decoder treats the record as invalid.

In one embodiment, atom regeneration includes a deterministic normalization behavior so that coefficient magnitudes have a consistent meaning across atoms. In one embodiment, atoms are normalized to unit energy over the processing unit support, and a normalization factor is obtained from parameters that depend on prime identifier and width parameter. In another embodiment, atoms are not normalized to unit energy and normalization is folded into coefficient interpretation, and the coefficient domain includes a declared scale factor that is applied consistently.

In one embodiment, a deterministic coefficient magnitude threshold is used for spike omission decisions so that small coefficients are not recorded when they would not materially reduce residual size under the declared policy. In one embodiment, the magnitude threshold is zero for lossless mode so that any selected spike is recorded if selected. In another embodiment, the magnitude threshold is nonzero and is declared and fixed by profile so that decisions are reproducible. In near-lossless and lossy embodiments, magnitude thresholding can be used to bound spike list size and to favor coding efficiency.

In one embodiment, a deterministic candidate restriction policy reduces computation while maintaining defined behavior. In one embodiment, candidate primes are restricted to a deterministic subset for a given processing unit size and sampling configuration, such as restricting to primes whose corresponding center frequencies fall within a declared band. In one embodiment, candidate centers are restricted to a deterministic subset based on a declared stride and a declared boundary rule. In one embodiment, candidate variants are restricted to a deterministic subset based on configuration.

In one embodiment, the sparse decomposition selection metric includes deterministic weighting to balance representation quality and coding cost. In one embodiment, a penalized metric is used that subtracts a deterministic coding-cost estimate from the correlation magnitude, where the coding-cost estimate depends on prime identifier rank, center identifier delta, and coefficient magnitude class, and the estimate uses fixed tables or formulas declared by profile. In that embodiment, the selection metric depends only on known identifiers and current residual correlations, and selection remains reproducible.

In one embodiment, a deterministic spike budget selection policy is used that depends on configuration and mode. In one embodiment, the spike budget is fixed per profile. In another embodiment, the spike budget is selected from a small finite set based on signal class and sampling configuration, and the selection rule is deterministic and signaled. In one embodiment, the spike budget is capped by a maximum that is validated by the decoder, and the spike count in a record does not exceed the declared budget.

In one embodiment, coefficient scaling can be performed per record to improve coding efficiency while preserving deterministic interpretation. In one embodiment, the encoder selects a scaling exponent such that the largest coefficient magnitude in the record fits within a target bit width, and the scaling exponent is encoded in the record header. In that embodiment, coefficients are encoded as integers representing scaled coefficient values, and the decoder reconstructs coefficients by applying the inverse scaling. In one embodiment, the scaling exponent selection is deterministic given the coefficients and uses a declared tie-breaking rule when multiple exponents satisfy the condition.

In one embodiment, residual predictor configuration includes deterministic selection of predictor type. In one embodiment, the predictor is fixed by profile. In another embodiment, the encoder selects among a finite set of predictor types by evaluating a deterministic cost metric on the residual or on the input block and selecting the lowest-cost predictor, and the selected predictor type is encoded in the record header. In that embodiment, the cost metric and evaluation procedure are deterministic and depend only on block values and finite computations.

In one embodiment, audio residual prediction uses a fixed linear predictor family. In one embodiment, a first-order predictor predicts the current residual sample from the immediately preceding residual sample. In another embodiment, a second-order predictor predicts from the two preceding residual samples. In one embodiment, predictor warm-up at the start of a block uses deterministic initialization values, such as treating missing previous samples as zeros or using the first sample as the initial previous sample, and the rule is declared.

In one embodiment, image and video residual prediction uses a fixed spatial predictor family within tiles. In one embodiment, a predictor uses the left neighbor pixel. In one embodiment, a predictor uses the above neighbor pixel. In one embodiment, a predictor uses a combination of left and above neighbors with a declared rounding rule. In one embodiment, boundary handling at tile edges uses deterministic initialization values or deterministic neighbor substitution rules. In one embodiment, a deterministic chroma handling policy is applied to maintain consistent decode behavior. In one embodiment, luma and chroma planes are coded separately with independent residual predictors. In another embodiment, luma-derived contexts influence chroma coefficient coding using deterministic context selection rules derived from already decoded luma identifiers and statistics. In one embodiment, chroma subsampling and resampling are applied under deterministic filters and rounding rules.

In one embodiment, a deterministic high-bit-depth handling policy is applied. In one embodiment, pixel bit depth is treated as part of configuration and determines output-domain saturation bounds and residual integer widths. In one embodiment, residual coding uses integer widths sufficient to represent differences without overflow. In one embodiment, coefficient mapping rules are selected so that intermediate computations do not overflow declared accumulator widths.

In one embodiment, deterministic overflow prevention is achieved by bounding coefficient ranges and by using declared accumulator widths. In one embodiment, coefficient magnitudes are bounded by a declared maximum magnitude, and values exceeding the maximum are saturated at the maximum under a declared rule. In one embodiment, multiplication results are computed in an extended intermediate width and then rounded back to a declared accumulation width. In one embodiment, if saturation occurs, residual definition in lossless mode is formed after saturation so that exact reconstruction remains possible.

In one embodiment, deterministic underflow and denormal handling is defined for floating-point internal computations. In one embodiment, denormal values are flushed to zero under a declared rule, and the rule is consistent across encoder and decoder implementations that use floating-point. In one embodiment, if floating-point internal computations are used, lossless output remains guaranteed by integer-domain residual definition and exact residual coding as described earlier.

In one embodiment, a deterministic energy computation rule is defined for near-lossless criteria. In one embodiment, energy is computed as a sum of squares in an integer or fixed-point domain with declared scaling. In one embodiment, energy is computed over a declared index range corresponding to the processing unit support. In one embodiment, when multiple channels are present, energy is computed per channel and combined by summation under a declared rule, or energy is computed on a transformed representation under a declared rule.

In one embodiment, a deterministic maximum error computation rule is defined for near-lossless criteria. In one embodiment, maximum absolute error is computed as the maximum of absolute differences between original integers and reconstructed integers at each position, and the maximum is computed deterministically. In one embodiment, the maximum error bound is declared per channel for audio or per plane for video, and satisfaction of the bound is evaluated deterministically.

In one embodiment, deterministic configuration negotiation is supported when a stream is transmitted between endpoints. In one embodiment, endpoints negotiate supported profiles and select a profile identifier that implies dictionary and coding semantics. In one embodiment, if negotiation fails, a fallback profile is selected deterministically from a declared preference order. In one embodiment, deterministic indexing and partial decode are supported by ensuring that record semantics do not require hidden long-range state. In one embodiment, restart points ensure that any adaptive coder and predictor state is reset so that decoding can begin at a restart point. In one embodiment, indexing maps desired time or frame positions to restart points and record offsets. In one embodiment, tile-level partial decode is supported by allowing independent decode of tile records when coding and predictor state are local to tiles or reset at tile boundaries under declared rules.

In one embodiment, deterministic verification uses reference payloads and reference outputs. In one embodiment, a test vector includes an original processing unit, an encoded record, and a reference reconstructed unit, and an implementation is verified by decoding the encoded record and comparing the reconstructed unit to the reference. In one embodiment, lossless verification checks exact equality of integer outputs. In one embodiment, near-lossless verification checks satisfaction of declared objective criteria.

In one embodiment, deterministic reporting of decode errors is provided. In one embodiment, when a record fails integrity validation, an error is reported and the record is skipped. In one embodiment, when a record fails bounds validation, an error is reported and decoding is halted or the record is skipped under a declared policy. In one embodiment, when a resynchronization marker is found after corruption, decoding resumes at that marker under a declared policy. In one embodiment, atom envelopes and oscillatory terms are generated using deterministic lookup tables whose contents are fixed for a profile, enabling consistent regeneration across hardware and software implementations. In one embodiment, a Gaussian envelope table stores values for a range of integer offsets and a range of width parameters represented in a declared fixed-point domain, and the envelope value for a given offset and width is obtained by table lookup with deterministic interpolation or by nearest-neighbor selection under a declared rule. In one embodiment, a cosine table stores values for a range of phase indices, and phase indices are advanced deterministically based on prime identifier and sample index.

In one embodiment, a phase accumulator is used for oscillatory term generation so that cosine evaluation is reduced to table indexing. In one embodiment, for a given prime identifier resolving to p and a base frequency parameter yielding an angular increment omega0, the phase increment per sample is p*omega0, and the phase accumulator is advanced by that increment at each sample index under a declared fixed-point representation. In one embodiment, the phase accumulator wraps modulo a declared phase modulus, and the wrap rule is deterministic. In one embodiment, a discrete phase variant identifier adds a fixed offset to the phase accumulator at the atom center, and the offset is selected from a finite set declared by profile.

In one embodiment, atom generation is centered at a center position by defining an offset index d=n−n0 and generating envelope values as a function of d while generating oscillatory values as a function of n under a declared rule. In one embodiment, envelope symmetry around d=0 is exploited so that only nonnegative offsets are stored in a table and negative offsets reuse the same values. In one embodiment, envelope values for offsets outside a declared support window are treated as zero, and the support window length is a deterministic function of width sigma and profile-defined truncation rules.

In one embodiment, atom support truncation is deterministic to reduce compute while preserving defined reconstruction semantics. In one embodiment, the envelope is considered negligible outside a deterministic multiple of sigma, such as a fixed number of sigma units, and atom values outside that window are set to zero. In one embodiment, the truncation multiple is fixed by profile. In one embodiment, truncation is applied identically at encoder and decoder. In one embodiment, in lossless mode, any truncation-induced mismatch is compensated by the exact residual as defined earlier.

In one embodiment, coefficient extraction includes deterministic normalization by atom energy to reduce dependence on atom scaling. In one embodiment, the coefficient is computed as a_n=<r, g>/<g, g> using deterministic arithmetic for numerator and denominator and a deterministic division or reciprocal approximation rule. In one embodiment, <g, g> values are precomputed and stored as fixed-point constants for each prime and width parameter and fetched from a parameter table. In one embodiment, division is avoided by multiplying by a precomputed reciprocal stored in a table, and reciprocal values are represented in fixed-point with declared scaling and rounding.

In one embodiment, inner product computation uses deterministic reduction ordering to avoid nondeterministic summation differences. In one embodiment, sums are computed in a fixed tree structure, such as a binary reduction tree with a fixed pairing of terms. In one embodiment, when parallel computation is used, partial sums are computed per thread or per lane and combined using a fixed reduction tree. In one embodiment, when fixed-point arithmetic is used, reduction ordering is less sensitive to associativity differences, but reduction ordering is still fixed to make behavior reproducible.

In one embodiment, tile separable projection uses deterministic intermediate quantization to bound intermediate ranges and preserve reproducibility. In one embodiment, row projections are computed into an intermediate fixed-point format with declared scaling, and intermediate results are rounded under a declared rule. In one embodiment, column projections consume the rounded intermediate values, and the rounding rule is part of the deterministic computation. In one embodiment, if intermediate rounding introduces mismatch, the residual completes exact reconstruction in lossless mode.

In one embodiment, coefficient coding uses deterministic binning of magnitudes into classes to reduce model complexity. In one embodiment, coefficient magnitudes are mapped to magnitude classes by a declared threshold table. In one embodiment, a class identifier is entropy-coded, and then an offset within the class is coded. In one embodiment, the threshold table is fixed by profile and is shared by encoder and decoder.

In one embodiment, prime identifiers and center identifiers are coded with deterministic context selection that depends on already decoded values. In one embodiment, prime identifier contexts are selected based on recent prime ranks, and center identifier contexts are selected based on recent center deltas. In one embodiment, context state is updated deterministically and reset at restart points. In one embodiment, context selection does not depend on any hidden state that is not reset and not derived from decoded symbols.

In one embodiment, error accumulation in near-lossless mode is bounded by deterministic policy choices. In one embodiment, when residual is coded at reduced precision, the reduced precision rule is applied by a deterministic quantizer with a declared step size, and the decoder reconstructs residual values by multiplying decoded quantized values by the same step size. In one embodiment, when residual is omitted, the omission policy is declared and objective measures are used to characterize reconstruction behavior.

In one embodiment, adaptive dictionary extensions are transmitted as parameter sets rather than as raw waveforms to preserve compactness and deterministic regeneration. In one embodiment, a supplementary atom is represented by a small set of parameters that map into the same atom generator used for base atoms, such as an effective prime identifier, an effective width identifier, a phase identifier, and an amplitude normalization identifier. In one embodiment, supplementary atom parameters are quantized to a declared grid and encoded as integers. In one embodiment, supplementary atom count is bounded and validated by the decoder.

In one embodiment, an encoder selects whether to use supplementary atoms for a processing unit under a deterministic rule, such as enabling supplementary atoms only after the supplementary table has been fully transmitted and validated, and selecting from supplementary atoms using the same deterministic selection and tie-breaking rules used for base atoms. In one embodiment, a decoder regenerates supplementary atoms using the same deterministic parameter interpretation and uses them only when indicated as enabled.

In one embodiment, when both base atoms and supplementary atoms are enabled, identifier spaces are partitioned deterministically. In one embodiment, prime identifiers in a certain range represent base primes and prime identifiers in another range represent supplementary entries, and the mapping is declared and validated. In one embodiment, the decoder resolves identifiers using the declared partitioning, avoiding ambiguity.

In one embodiment, a deterministic memory layout is used for spike list storage and parsing. In one embodiment, spike entries are stored as packed fields with fixed widths for prime identifier and center identifier and variable widths for coefficients as determined by the coding scheme. In one embodiment, the decoder reconstructs spike entries into a canonical in-memory representation before atom regeneration, and field parsing is deterministic.

In one embodiment, a deterministic scheduling policy is used when hardware acceleration is present. In one embodiment, the control processor schedules correlation computations and argmax selection in fixed phases per processing unit, and record emission follows a deterministic order. In one embodiment, when parallel processing is used, outputs are committed in a deterministic record order and any nondeterministic completion order is reconciled by ordering outputs before packer emission.

In one embodiment, a deterministic policy is used for switching modes per record when mode switching is permitted. In one embodiment, mode switching is restricted to restart points. In another embodiment, mode switching is permitted per record and is encoded explicitly in the record header, and the decoder applies the mode policy indicated. In each case, mode switching is defined by explicit fields and does not rely on implicit state.

In one embodiment, the decoded output is used to drive subsequent processing systems that require machine-actionable determinism. In one embodiment, decoded telemetry values are consumed by a control system that expects consistent reconstruction semantics. In one embodiment, decoded medical images are consumed by image processing systems that expect pixel-exact reconstruction. In one embodiment, decoded studio masters are consumed by mastering pipelines that expect identical sample values across repeated decodes in lossless mode. In one embodiment, an encoder uses a deterministic per-record decision rule to choose between coding a larger spike list with a smaller residual and coding a smaller spike list with a larger residual, while maintaining exact reconstruction in lossless mode. In one embodiment, the decision rule compares an estimated spike-list bit cost plus an estimated residual bit cost for candidate spike counts, where the cost estimates are computed from fixed models and declared coding parameters. In one embodiment, the encoder evaluates a small finite set of candidate spike counts, such as from 0 to a maximum budget, and selects the spike count that yields the minimum estimated total bit cost, and the selection procedure is deterministic.

In one embodiment, residual bit cost estimation is computed by applying the residual predictor configuration to the candidate residual and estimating coding cost using a fixed error distribution model. In one embodiment, the model uses a deterministic mapping from error magnitudes to expected code lengths based on a fixed Rice parameter or a fixed arithmetic coding model. In one embodiment, spike-list bit cost estimation is computed from prime identifier ranks, center identifier distributions, and coefficient magnitude distributions using fixed models. In one embodiment, when the encoder uses these estimates, the chosen spike count and any associated decision outputs are not required to be transmitted because the record explicitly includes the resulting spike list and residual payload, and the decoder reconstructs from those payloads. In one embodiment, a deterministic per-record policy selects whether to include optional fields such as coefficient scaling exponents or context reset indicators, based on declared thresholds. In one embodiment, if the dynamic range of coefficients exceeds a threshold, a scaling exponent is included; otherwise coefficients are encoded using the default scaling. In one embodiment, if a record is designated as a restart point, a context reset indicator is included, and coder state is reset. In one embodiment, any optional field inclusion decision is based solely on record-local measurements and declared thresholds so that encoder behavior is reproducible.

In one embodiment, a deterministic policy defines when a record is considered a restart record. In one embodiment, restart records are inserted at fixed intervals in units of blocks, tiles, frames, or time, and the interval is declared. In one embodiment, restart records are also inserted at boundaries such as keyframe boundaries for video or segment boundaries for streaming sessions, and boundary selection is deterministic based on declared segmentation rules. In one embodiment, restart insertion does not alter reconstruction semantics for the record itself; it resets state for subsequent records.

In one embodiment, a deterministic policy defines per-plane and per-channel ordering for coding multi-plane or multi-channel content. In one embodiment, for YUV content, luma plane records are coded before chroma plane records for each frame, and chroma planes are coded in a declared order. In one embodiment, for multi-channel audio, channels are coded in a declared order, such as channel index order, or transformed channels are coded in a declared order. In one embodiment, plane or channel ordering is declared so a decoder associates decoded records with the correct output plane or channel.

In one embodiment, a deterministic policy defines how multi-plane tiles are grouped. In one embodiment, tiles for different planes at the same spatial location are grouped into a record group, and the group ordering is deterministic. In another embodiment, each plane's tiles are coded as separate records, and plane boundaries are explicit. In one embodiment, grouping choices are defined by profile.

In one embodiment, a deterministic policy defines how volumetric medical imaging data is coded. In one embodiment, slices are ordered by slice index and coded in that order. In one embodiment, within each slice, tiles are ordered by a deterministic tile traversal. In one embodiment, slice boundaries align to restart points so that decoding can begin at a slice boundary without decoding prior slices. In one embodiment, any slice-level metadata needed for ordering is carried outside the coded pixel payload or is carried in a header.

In one embodiment, a deterministic policy defines how telemetry channels are coded when multiple telemetry channels exist. In one embodiment, telemetry channels are coded in a declared channel order, and each channel uses a declared block size. In one embodiment, synchronization markers include channel identifiers so a decoder can align channel streams deterministically. In one embodiment, if channels are combined into a composite record, the composite record includes explicit lengths for each channel payload.

In one embodiment, a deterministic policy defines the handling of end-of-stream conditions. In one embodiment, end-of-stream is indicated by a terminal marker record. In one embodiment, the last processing unit includes a valid-length indicator that specifies how many samples or pixels are valid when padding is used. In one embodiment, the decoder discards padded values after reconstruction based on the valid-length indicator. In one embodiment, if the stream is truncated unexpectedly, the decoder reports truncation and outputs only fully verified records. In one embodiment, deterministic decode behavior is maintained under partial decoding and seeking by ensuring that any state required for decoding is either (i) derived solely from already decoded records after a restart point or (ii) explicitly present in the stream header or in the restart record. In one embodiment, arithmetic coder models are reset at restart points. In one embodiment, predictors are reset at restart points. In one embodiment, any adaptive dictionary state is reset or fully specified at restart points.

In one embodiment, a deterministic cache strategy is used for atom regeneration to reduce compute. In one embodiment, regenerated one-dimensional atoms are cached per prime identifier and per center class for a processing unit size, and the cache is keyed deterministically. In one embodiment, cache eviction uses a deterministic policy, such as least-recently-used with deterministic tie-breaking, so that cache behavior does not affect results. In one embodiment, caching does not change atom values; it only reduces repeated generation.

In one embodiment, deterministic parallel execution is supported by requiring that any non-associative operations that could yield different results under different operation ordering are either performed in a fixed-point domain with declared rounding or are corrected by integer-domain residual definition in lossless mode. In one embodiment, encoder and decoder both use the same fixed-point domain for atom generation and accumulation. In another embodiment, encoder and decoder can differ internally while lossless output remains guaranteed because residuals are defined and coded in the integer output domain.

In one embodiment, deterministic logging is supported for audit without conditioning reconstruction on the log. In one embodiment, the encoder records per-record statistics such as spike count, prime identifier histogram, coefficient magnitude histogram, and residual size. In one embodiment, the decoder can record analogous statistics. In one embodiment, logs are stored externally and do not affect decoding.

In one embodiment, deterministic interoperability is supported by requiring that profile identifiers correspond to fixed published semantics for constants, mapping rules, dictionary bounds, coding methods, and mode policies. In one embodiment, implementations that claim support for a profile decode streams for that profile identically in lossless mode and satisfy the declared objective criteria in near-lossless mode. In one embodiment, if an implementation does not support a profile, it rejects the stream rather than attempting to decode under guessed semantics.

In one embodiment, a deterministic ordering is used for evaluating candidates during sparse selection so that selection results do not depend on implementation-specific iteration order. In one embodiment, the ordering enumerates prime identifiers in increasing order, enumerates center identifiers in increasing order within each prime, and enumerates enabled variant identifiers in increasing order within each center, and candidate enumeration follows that ordering for every processing unit. In one embodiment, when candidate restriction policies are active, the restriction is applied by selecting a deterministic subset of this ordered sequence, and the subset selection rule is declared.

In one embodiment, a deterministic tolerance policy is used when comparisons are performed in a floating-point domain. In one embodiment, correlation values are quantized to a fixed-point compare domain before comparison, and comparisons are performed in the fixed-point compare domain. In another embodiment, a declared tolerance is used and correlation values within tolerance are treated as equal, and the tolerance value is fixed by profile. In one embodiment, the tie-breaking rule selects the earlier candidate in the declared enumeration order when candidates compare equal.

In one embodiment, deterministic selection is maintained when using GPU parallel reduction by encoding identifiers into comparison keys. In one embodiment, each candidate's correlation magnitude is paired with a composite identifier value derived from prime identifier, center identifier, and variant identifier, and reduction compares correlation magnitudes first and compares composite identifier values second under a declared order. In one embodiment, the composite identifier ordering corresponds to the declared enumeration order. In one embodiment, reduction produces a unique selected candidate even when correlation magnitudes compare equal.

In one embodiment, deterministic coefficient sign handling is defined. In one embodiment, coefficients are stored as signed integers and the sign is part of the coefficient field. In another embodiment, coefficients are stored as nonnegative magnitudes and the sign is encoded as a separate sign bit. In another embodiment, sign is encoded as part of a discrete variant identifier that selects an atom multiplied by +1 or −1, and coefficients are stored as nonnegative magnitudes. In each case, the choice is fixed by profile or signaled explicitly, and the decoder reconstructs the signed coefficient deterministically.

In one embodiment, deterministic coefficient clipping and saturation are defined to avoid undefined overflow. In one embodiment, coefficient magnitudes are limited to a declared maximum magnitude, and values exceeding the maximum are saturated at the maximum before coding. In one embodiment, saturation is performed in the coefficient domain and is applied consistently at encoder and decoder. In one embodiment, residual definition in lossless mode is formed after saturation so that exact reconstruction remains possible.

In one embodiment, deterministic residual integer width is defined so that residual differences do not overflow. In one embodiment, residuals are represented in an integer width larger than the output sample width, such as using a wider signed integer type for residuals, and residual addition at decode is performed in that wider type before mapping to the output width under a declared rule. In one embodiment, residual coding encodes residuals as signed integers in that wider domain, and decoding reconstructs those integers exactly in lossless mode.

In one embodiment, deterministic handling of signed-to-unsigned mapping for entropy coding is defined. In one embodiment, signed integers are mapped to nonnegative integers using a bijection in which 0 maps to 0, −1 maps to 1, +1 maps to 2 , −2 maps to 3, +2 maps to 4, and so on. In one embodiment, the inverse mapping is applied at decode. In one embodiment, the mapping is fixed by profile so encoder and decoder apply the same mapping.

In one embodiment, deterministic handling of run-length coding is defined for sequences of repeated symbols. In one embodiment, residual prediction errors that are zero are run-length coded using a declared run-length code. In one embodiment, runs are bounded by a declared maximum length and long runs are split deterministically. In one embodiment, the decoder reconstructs runs deterministically.

In one embodiment, deterministic handling of coefficient zeroing is defined. In one embodiment, when a coefficient magnitude is zero after quantization in near-lossless or lossy modes, the spike entry is omitted entirely rather than encoded with a zero coefficient, and omission rules are deterministic. In another embodiment, zero coefficients are allowed and are encoded using a declared code. In each case, the chosen rule is declared and reproducible.

In one embodiment, deterministic handling of variant identifiers is defined when variants are enabled. In one embodiment, a finite set of phase variants is defined and each phase variant has an integer identifier. In one embodiment, phase variants correspond to fixed phase offsets. In one embodiment, the decoder applies the phase offset by adjusting a phase accumulator or by selecting a phase offset in a cosine table. In one embodiment, when phase variants are disabled, variant identifiers are absent and atom generation uses a default phase.

In one embodiment, deterministic handling of width variants is defined when width variants are enabled. In one embodiment, a finite set of width multipliers is defined and each width multiplier has an integer identifier. In one embodiment, width multipliers are applied to a base width parameter to obtain an effective width. In one embodiment, effective widths are represented in a fixed-point form with declared scaling. In one embodiment, the decoder applies the same width multiplier mapping and regenerates the same envelope shape.

In one embodiment, deterministic handling of separable axis parameters is defined for two-dimensional tiles. In one embodiment, horizontal and vertical axis parameters are derived from tile width and tile height under declared mapping rules. In one embodiment, horizontal and vertical prime identifier bounds can differ because axis sizes differ, and bounds are derived deterministically. In one embodiment, the decoder regenerates horizontal and vertical atoms using the corresponding axis parameters.

In one embodiment, deterministic tile boundary and coordinate handling is defined. In one embodiment, tile coordinates are derived from tile index and frame dimensions under a declared traversal. In one embodiment, tile origin and placement in the reconstructed plane are computed deterministically. In one embodiment, padding regions are identified deterministically and discarded after reconstruction based on original frame dimensions.

In one embodiment, deterministic multi-plane reconstruction is defined. In one embodiment, each plane is reconstructed from its tiles and placed into a plane buffer. In one embodiment, plane buffers are combined into frames under a declared plane order. In one embodiment, if color conversion is applied, conversion is performed using declared coefficients and rounding rules.

In one embodiment, deterministic multi-channel reconstruction is defined. In one embodiment, channels are reconstructed independently and then combined into a multi-channel stream. In one embodiment, if a reversible channel transform was applied at encode, the inverse transform is applied deterministically at decode to reconstruct original channels exactly in lossless mode. In one embodiment, deterministic output formatting is defined. In one embodiment, reconstructed samples or pixels are output in the same numeric type and bit depth as the input domain for lossless mode. In one embodiment, reconstructed outputs are clipped or saturated under a declared rule to the representable range when required by the output format. In one embodiment, output metadata reflects the declared configuration used for decoding.

In one embodiment, deterministic profile enforcement is performed. In one embodiment, a decoder maintains a table of supported profile identifiers and corresponding semantics and rejects unsupported profile identifiers. In one embodiment, a decoder validates that record fields conform to semantics for the selected profile. In one embodiment, if validation fails, decoding is halted or the record is skipped under a declared policy.

In one embodiment, a deterministic set of implementation targets is supported by providing a stable mapping from configuration inputs to per-record compute budgets and memory budgets. In one embodiment, the maximum spike count, candidate enumeration scope, coefficient representation, and residual predictor configuration jointly define a worst-case compute bound per processing unit. In one embodiment, those bounds are used to provision buffers and to size fixed-function hardware pipelines.

In one embodiment, a deterministic GPU implementation uses a fixed kernel launch configuration derived from processing unit size and candidate enumeration scope. In one embodiment, each thread block processes a fixed subset of prime identifiers and center identifiers. In one embodiment, partial correlation sums are computed in a fixed order within a thread and reduced within a thread block using a fixed reduction tree. In one embodiment, per-block reduction produces a candidate maximum and associated identifiers, and a second-stage reduction combines per-block results using a fixed reduction tree and deterministic tie-breaking based on identifiers.

In one embodiment, a deterministic FPGA implementation uses fixed pipelines for envelope generation, oscillatory generation, multiplication, and accumulation. In one embodiment, envelope generation uses fixed-point lookup tables stored in on-chip memory. In one embodiment, oscillatory generation uses a phase accumulator and a cosine lookup table. In one embodiment, dot products are computed using a fixed multiply-accumulate pipeline, and partial sums are combined using a fixed adder tree. In one embodiment, argmax selection is implemented as a fixed comparator tree that compares correlation magnitudes and then compares identifiers under deterministic tie-breaking.

In one embodiment, a deterministic ASIC decode-only implementation regenerates atoms using fixed-point tables and applies coefficients using fixed-point multiplication and accumulation. In one embodiment, spike list decoding is implemented as a finite state machine that parses a record header, parses a declared number of spike entries, and parses a residual payload when present. In one embodiment, residual decoding uses a fixed predictor and fixed entropy decoding logic. In one embodiment, reconstruction uses a fixed mapping rule to map sparse estimates to the integer output domain and adds decoded residuals to obtain output integers.

In one embodiment, deterministic verification for hardware implementations includes decoding reference records and comparing reconstructed outputs to stored reference outputs. In one embodiment, verification is performed at manufacturing time by decoding a stored reference payload and checking exact equality of outputs in lossless mode. In one embodiment, verification is performed at deployment time by decoding a reference stream and reporting a pass/fail status.

In one embodiment, deterministic behavior across heterogeneous implementations is achieved by using exact integer-domain residual definition and exact residual coding for lossless mode. In one embodiment, correlation computations and coefficient extraction may differ slightly across implementations due to arithmetic differences, but the integer-domain mapping and residual definition at the encoder and the same mapping and residual combination at the decoder ensure exact output equality in lossless mode. In one embodiment, for near-lossless and lossy modes, objective criteria and deterministic truncation policies ensure reproducible behavior for a given input and profile.

In one embodiment, a deterministic distributed encoding workflow partitions a large input into segments that begin at restart points. In one embodiment, each segment is encoded independently because restart points reset adaptive coder state and predictor state to declared initial states. In one embodiment, encoded segments are concatenated to form a complete stream, and decoding can begin at any segment boundary corresponding to a restart point. In one embodiment, distributed decoding similarly decodes segments independently starting from restart points.

In one embodiment, deterministic cloud-scale operation is supported by recording profile identifiers and configuration values used for each encoding job and ensuring that the same profile identifiers and configuration values yield the same reconstruction semantics. In one embodiment, job scheduling and instance variability do not affect decoded outputs in lossless mode because reconstruction depends on decoded fields and exact residual combination rules. In one embodiment, near-lossless and lossy outputs remain reproducible for a given input and profile because truncation and quantization policies are fixed.

In one embodiment, deterministic device-scale decode is supported by limiting profile complexity. In one embodiment, a portable endpoint supports a bounded prime set and a bounded center grid and uses fixed-point tables for atom regeneration. In one embodiment, memory usage is bounded by a declared maximum spike count and processing unit size. In one embodiment, streaming decode uses bounded buffering and restart points to recover from packet loss deterministically.

In one embodiment, deterministic interoperability is supported by associating each encoded stream with a profile identifier that defines the mapping rules, dictionary bounds, coding methods, and mode semantics. In one embodiment, profile identifiers correspond to published semantics so that independent implementations can decode streams consistently. In one embodiment, profile identifiers also define allowed parameter ranges and validation rules to prevent ambiguous interpretation.

In one embodiment, deterministic support for audit and compliance is provided by generating integrity metadata and logs that do not alter reconstruction. In one embodiment, per-record checksums are included. In one embodiment, per-stream hashes of original and reconstructed content are stored externally. In one embodiment, logs record spike counts, residual sizes, and profile identifiers, and logs can be used to verify that decoding behavior conforms to declared semantics.

In one embodiment, deterministic handling of update and compatibility is supported by version identifiers that constrain decoding semantics. In one embodiment, new versions add optional fields that are ignored by decoders that do not support them only when ignoring those fields does not affect reconstruction; otherwise unsupported versions are rejected. In one embodiment, forward compatibility is achieved by requiring unknown critical fields to trigger rejection, preventing silent mis-decoding.

In one embodiment, deterministic behavior under partial record loss is supported by ensuring that each record is self-delimiting and that restart points provide recovery boundaries. In one embodiment, missing records are flagged and output gaps are produced deterministically. In one embodiment, concealment fills are produced deterministically under a declared policy when concealment is enabled.

In one embodiment, deterministic behavior under malformed inputs is supported by strict validation of decoded values and strict bounds checking. In one embodiment, spike counts exceeding declared limits cause rejection. In one embodiment, identifiers outside declared ranges cause rejection. In one embodiment, length fields inconsistent with buffer lengths cause rejection. In one embodiment, arithmetic coder state inconsistencies cause rejection. In one embodiment, rejection behavior is deterministic and does not produce undefined outputs.

1. A computer-implemented method of encoding an input signal, the method comprising:
receiving the input signal as discrete input values in an integer representation domain; partitioning the input signal into processing units, each processing unit comprising a block, frame, tile, slice, or other bounded subset of the input signal defined by a declared configuration; for a processing unit, deterministically deriving atom-definition parameters from (i) a sampling configuration, (ii) a processing-unit configuration, and (iii) profile-fixed constants shared by an encoder and a decoder under a declared profile, the atom-definition parameters defining a base frequency, an envelope width, and a deterministic center grid; forming, from the atom-definition parameters, a dictionary of candidate atoms that includes prime-indexed Gaussian-spike atoms whose center frequencies are determined as prime multiples of the base frequency and whose centers are determined by center identifiers from the deterministic center grid, wherein, in a lossless profile, the dictionary excludes non-prime frequency indices; performing a sparse decomposition of the processing unit by iteratively selecting, from the dictionary, atoms according to an objective selection metric that is deterministic under the declared profile and that applies a deterministic candidate ordering and tie-breaking rule, and recording for each selected atom (i) a prime identifier, (ii) a center identifier, and (iii) a coefficient, thereby producing a spike list and a sparse estimate; mapping the sparse estimate into the integer representation domain using a declared deterministic mapping rule to form an integer-domain sparse estimate; defining an integer-domain residual as an exact difference between the processing unit in the integer representation domain and the integer-domain sparse estimate; entropy coding (i) the spike list and (ii) the integer-domain residual to form a compressed bitstream including a header and payload fields; and outputting the compressed bitstream.

2. The method of claim 1, wherein deterministically deriving the atom-definition parameters comprises computing normalized parameters using profile-fixed constants including a golden-ratio-based constant, an X_opt constant derived from the golden-ratio-based constant, and an R_RP constant, and mapping the normalized parameters to the sampling configuration and the processing-unit configuration.

3. The method of claim 1, wherein the dictionary is bounded by a deterministic prime bound derived from a bandwidth constraint under the declared profile and the sampling configuration such that prime-indexed center frequencies do not exceed a Nyquist frequency equal to one-half of a sampling rate F_s associated with the sampling configuration.

4. The method of claim 1, wherein performing the sparse decomposition comprises selecting atoms by maximizing an absolute correlation between a current residual and a candidate atom, and applying, when candidates compare equal under a declared compare rule, a deterministic tie-breaking rule based on an ordered comparison of at least (i) prime identifiers in increasing order and, when equal, (ii) center identifiers in increasing order.

5. The method of claim 1, wherein the coefficients are represented in a fixed-point coefficient domain having a declared scaling rule, and wherein entropy coding the spike list includes entropy coding coefficient magnitudes using an arithmetic coder or range coder that applies a deterministic model update rule based only on previously coded coefficient magnitudes and that is reset to a declared initial state at a start of the bitstream or at each restart point.

6. The method of claim 1, wherein entropy coding the integer-domain residual comprises applying a reversible integer predictor to generate integer prediction errors and entropy coding the integer prediction errors using a Rice-family code or arithmetic/range coding under a declared predictor configuration, the declared predictor configuration defining predictor type, predictor order, predictor coefficients when used, predictor initialization, boundary handling, and signed-error interpretation in a manner reproducible at the decoder.

7. The method of claim 1, wherein the compressed bitstream includes restart points at deterministic intervals fixed by a profile identifier or signaled in a header, each restart point resetting at least one of (i) a residual predictor state, (ii) an adaptive entropy coding state, and (iii) a context state derived from prior records to a declared initial state, whereby decoding can begin at a restart point without decoding records prior to the restart point.

8. A computer-implemented method of decoding a compressed bitstream to reconstruct an input signal, the method comprising: receiving the compressed bitstream that includes, for a processing unit, a header, an encoded spike list, and an encoded residual; parsing the header to obtain a sampling configuration, a processing-unit configuration, and an atom-derivation configuration including at least a profile identifier and one or more mapping rule identifiers; decoding the encoded spike list to obtain spike entries each including at least (i) a prime identifier, (ii) a center identifier, and (iii) a coefficient; decoding the encoded residual to obtain an integer-domain residual in an integer representation domain; deterministically deriving, from the sampling configuration and the processing-unit configuration and the atom-derivation configuration, atom-definition parameters defining a base frequency, an envelope width, and a deterministic center grid; regenerating prime-indexed Gaussian-spike atoms referenced by the spike entries using the atom-definition parameters; accumulating a sparse estimate by summing regenerated atoms weighted by corresponding decoded coefficients; mapping the sparse estimate into the integer representation domain using the same declared deterministic mapping rule identified from the parsed header by the profile identifier or the one or more mapping rule identifiers to form an integer-domain sparse estimate; and reconstructing the processing unit as an integer-domain sum of the integer-domain sparse estimate and the integer-domain residual under a declared integer addition rule fixed by the profile identifier and defining addition width and overflow handling.

9. The method of claim 8, wherein reconstructing the input signal comprises assembling reconstructed processing units using overlap-add reconstruction for overlapped audio blocks under a declared hop size, declared windowing rules, and a declared normalization rule.

10. The method of claim 8, wherein the processing unit is a tile of an image plane, and reconstructing the input signal comprises assembling reconstructed tiles into a reconstructed plane using a deterministic tile placement rule derived from a declared tile traversal order and a deterministic padding removal rule.

11. The method of claim 8, wherein regenerating the prime-indexed Gaussian-spike atoms comprises deterministically generating, for a tile, a two-dimensional separable atom as a product of (i) a one-dimensional horizontal atom indexed by a horizontal prime identifier and a horizontal center identifier and (ii) a one-dimensional vertical atom indexed by a vertical prime identifier and a vertical center identifier.

12. The method of claim 8, further comprising validating that decoded prime identifiers and decoded center identifiers are within declared bounds for the sampling configuration and the processing-unit configuration, and, when a bound is violated, treating the record as invalid, discarding the record, and outputting a gap or concealment output for the processing unit as defined by the profile identifier or signaled in the header.

13. The method of claim 8, wherein the compressed bitstream includes restart points, and the method further comprises, at a restart point, resetting at least one of (i) a residual predictor state, (ii) an adaptive entropy coding state, and (iii) a context state derived from prior records to a declared initial state before decoding a subsequent processing-unit record.

14. The method of claim 8, further comprising detecting corruption of a processing-unit record using an integrity field, and, responsive to detecting corruption, treating the processing-unit record as invalid and applying a deterministic handling policy that includes at least one of discarding the record and producing a defined concealment output for the processing unit.

15. A system for encoding an input signal and producing a compressed bitstream, the system comprising: one or more processors; and a non-transitory memory storing instructions that, when executed by the one or more processors, cause the system to: receive the input signal as discrete input values in an integer representation domain; partition the input signal into processing units; for a processing unit, deterministically derive atom-definition parameters from (i) a sampling configuration, (ii) a processing-unit configuration, and (iii) profile-fixed constants shared by an encoder and a decoder under a declared profile, the atom-definition parameters defining a base frequency, an envelope width, and a deterministic center grid; generate or address, under the declared profile, a dictionary of candidate atoms that includes prime-indexed Gaussian-spike atoms whose center frequencies are determined as prime multiples of the base frequency and whose centers are determined by center identifiers from the deterministic center grid; perform, under the declared profile, a sparse decomposition to produce a spike list comprising, for each selected atom, at least a prime identifier, a center identifier, and a coefficient, and to produce a sparse estimate; map the sparse estimate into the integer representation domain using a declared deterministic mapping rule to form an integer-domain sparse estimate; define an integer-domain residual as an exact difference between the processing unit in the integer representation domain and the integer-domain sparse estimate; and entropy code the spike list and the integer-domain residual to output the compressed bitstream including header and payload fields, the header fields including at least a profile identifier that identifies the declared profile and governs interpretation of the header and payload fields, including interpretation of any mapping rule identifiers carried in the compressed bitstream.

16. The system of claim 15, wherein the instructions further cause the system to perform at least a portion of correlation computations for the sparse decomposition using a GPU accelerator or vectorized processor instructions while maintaining deterministic selection behavior by comparing candidates using a composite key that orders (i) a correlation magnitude metric and, when equal under a declared compare rule, (ii) at least prime identifier and center identifier ordering, and, when variants are enabled, variant identifier ordering, under the deterministic tie-breaking rule and a declared candidate enumeration order, and by reducing candidate comparison results according to a fixed reduction ordering.

17. A non-transitory computer-readable medium storing instructions that, when executed by one or more processors, cause the one or more processors to: receive an input signal as discrete input values in an integer representation domain; partition the input signal into processing units; for a processing unit, deterministically derive atom-definition parameters from (i) a sampling configuration, (ii) a processing-unit configuration, and (iii) profile-fixed constants shared by an encoder and a decoder under a declared profile, the atom-definition parameters defining a base frequency, an envelope width, and a deterministic center grid; generate or address, under the declared profile, a dictionary of candidate atoms that includes prime-indexed Gaussian-spike atoms whose center frequencies are determined as prime multiples of the base frequency and whose centers are determined by center identifiers from the deterministic center grid; perform, under the declared profile, a sparse decomposition to produce a spike list comprising, for each selected atom, at least a prime identifier, a center identifier, and a coefficient, and to produce a sparse estimate; map the sparse estimate into the integer representation domain using a declared deterministic mapping rule to form an integer-domain sparse estimate; define an integer-domain residual as an exact difference between the processing unit in the integer representation domain and the integer-domain sparse estimate; and entropy code the spike list and the integer-domain residual to output a compressed bitstream including header and payload fields, the header fields including at least a profile identifier that identifies the declared profile and governs interpretation of the header and payload fields, including interpretation of any mapping rule identifiers carried in the compressed bitstream.

18. The non-transitory computer-readable medium of claim 17, wherein the instructions further cause the one or more processors to generate atom values and apply coefficients in a fixed-point arithmetic domain or using lookup tables under declared scaling, normalization-factor, intermediate-width, accumulator-width, rounding, saturation, interpolation, table-indexing, table-interpretation, phase-increment interpretation, phase-accumulator wrapping, and operation-ordering rules shared by encoder and decoder.

19. The system of claim 15, wherein the instructions further cause the system to apply a reversible integer-domain multi-channel transform to multi-channel audio prior to sparse decomposition, the reversible integer-domain multi-channel transform including at least one of a mid/side transform and a difference-channel transform that represents one or more channels as integer differences relative to a reference channel, and to apply a corresponding inverse transform after decoding.

20. The system of claim 15, wherein the instructions further cause the system to encode, for each processing-unit record, a record header that includes at least a mode indicator, a spike count, a residual-present indicator, and at least one explicit payload length field for a spike-list payload or a residual payload, sufficient to enable a decoder to determine how many spike entries are present, whether a residual payload is present, whether payload lengths are consistent with the record header, whether the decoder can validate the record without parsing arbitrary prior records, whether the decoder can bound record-local memory allocation without parsing arbitrary prior records, and whether the decoder can skip forward by length to a subsequent record boundary without parsing arbitrary prior records.
